(19) United States
(12) Patent Application Publication
(10) Pub. No.: US 2025/0154402 A1
(43) Pub. Date: May 15, 2025

(54) QUANTUM DOT MATERIAL, LIGHT-EMITTING DEVICE AND MANUFACTURING METHOD THEREFOR, AND DISPLAY APPARATUS

(71) Applicant: BOE TECHNOLOGY GROUP CO., LTD., Beijing (CN)

(72) Inventor: Bing FANG, Beijing (CN)

(73) Assignee: BOE TECHNOLOGY GROUP CO., LTD., Beijing (CN)

(21) Appl. No.: 18/837,893

(22) PCT Filed: Sep. 1, 2022
(86) PCT No.: PCT/CN2022/116455

§ 371 Date: Aug. 13, 2024

(51) Int. Cl. C09K 11/02; C09K 11/54; H10H 20/01; H10H 20/812; H10H 20/813

(52) U.S. Cl. CPC C09K 11/02; C09K 11/54; H10H 20/011; H10H 20/812; H10H 20/8132; C09K 2211/1011

(57) ABSTRACT

A quantum dot material includes a quantum dot body and a ligand material coordinately bonded to the quantum dot body. The quantum dot material further includes a cross-linking agent, and the cross-linking agent includes at least two diazonaphthoquinone units. Each of the at least two diazonaphthoquinone units is configured to undergo a photochemical reaction under irradiation to generate a carbene intermediate; the ligand material is configured to be bonded to the carbene intermediate through an addition reaction to form a cross-linked quantum dot material.

### CROSS-REFERENCE TO RELATED APPLICATION

The present application is a national phase entry under 35 USC 371 of International Patent Application No. PCT/CN2022/116455, filed on Sep. 1, 2022, which is incorporated herein by reference in its entirety.

### TECHNICAL FIELD

The present disclosure relates to the field of display technologies, and in particular, to a quantum dot material, a light-emitting device and manufacturing method therefor, and a display apparatus.

### BACKGROUND

Organic light-emitting diodes (OLEDs), quantum dot light-emitting diodes (QLEDs) and quantum dot organic light-emitting diodes (QDOLEDs) and other light-emitting diodes have advantages such as self-luminous, wide viewing angle, fast response time, high luminous efficiency, low operating voltage, small substrate thickness, ability to produce large-sized and bendable substrates, and simple manufacturing process, and have become more and more widely used in recent years.

### SUMMARY

In an aspect, a quantum dot material is provided. The quantum dot material includes: a quantum dot body and a ligand material coordinately bonded to the quantum dot body. The quantum dot material further includes a cross-linking agent; the cross-linking agent includes at least two diazonaphthoquinone units. Each diazonaphthoquinone unit of the at least two diazonaphthoquinone units is configured to undergo a photochemical reaction under irradiation to generate a carbene intermediate; the ligand material is configured to be bonded to the carbene intermediate through an addition reaction to form a cross-linked quantum dot material.

In some embodiments, the ligand material includes an alkyl carbon-hydrogen bond, and the alkyl carbon-hydrogen bond of the ligand material is configured to be bonded to the carbene intermediate through a carbon-hydrogen insertion addition reaction. Alternatively, the ligand material includes a hydroxyl group, and the hydroxyl group in the ligand material is configured to be bonded to the carbene intermediate through an addition reaction to form an ether compound. Alternatively, the ligand material includes an amino group, and the amino group in the ligand material is configured to be bonded to the carbene intermediate through a nitrogen-hydrogen insertion addition reaction. Alternatively, the ligand material includes a carboxyl group, and the carboxyl group in the ligand material is configured to be bonded to the carbene intermediate through an addition reaction to form an ester compound.

In some embodiments, the cross-linking agent is selected from any one of structures represented by following general formula I;

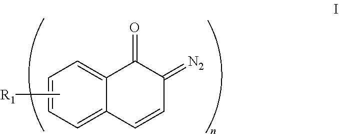

where R₁ is selected from any one of substituted or unsubstituted alkanes, substituted or unsubstituted heterocyclic compounds, and substituted or unsubstituted aromatic hydrocarbons, and a value of n is selected from an integer greater than or equal to 2.

In some embodiments, the value of n is selected from any one of 2, 3, 4, 5 and 6.

In some embodiments, the cross-linking agent is selected from any one of structures represented by following general formula I-A;

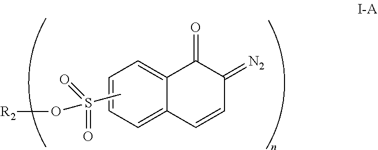

where R₂ is selected from any one of substituted or unsubstituted alkanes, substituted or unsubstituted heterocyclic compounds, and substituted or unsubstituted aromatic hydrocarbons, and a value of n is selected from an integer greater than or equal to 2.

In some embodiments, the ligand material includes any one of oleic acid, oleylamine, isooctylthiol and octylthiol.

In some embodiments, a mass of the cross-linking agent accounts for 5% to 10% of a mass of the quantum dot body.

In some embodiments, the formed cross-linked quantum dot material is selected from any one of structures represented b following general formula II;

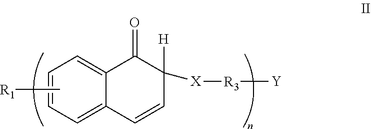

where X is selected from any one of single bonds, oxygen groups, imino groups, and ester groups; R₃ is selected from any one of —COO— containing C1-C40 carbon chains, —NH— containing C1-C40 carbon chains, —S— containing C1-C40 carbon chains, and organophosphorus compounds containing C1-C40 carbon chains; R₁ is selected from any one of substituted or unsubstituted alkanes, substituted or unsubstituted heterocyclic compounds, and substituted or unsubstituted aromatic hydrocarbons; a value of n is selected from an integer greater than or equal to 2; and Y represents the quantum dot body.

In some embodiments, the formed cross-linked quantum dot material is selected from any one of structures represented by following general formula II-A;

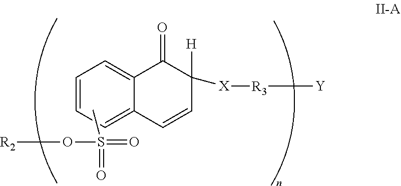

R₂ is selected from any one of substituted or unsubstituted alkanes, substituted or unsubstituted heterocyclic compounds, and substituted or unsubstituted aromatic hydrocarbons.

In some embodiments, a solubility of the cross-linked quantum dot material in a non-polar solvent is less than a solubility of the quantum dot material in the non-polar solvent.

In some embodiments, the non-polar solvent includes any one of octane, toluene and xylene.

In another aspect, a light-emitting device is provided. The light-emitting device includes a light-emitting layer, and the light-emitting layer includes the cross-linked quantum dot material formed by the quantum dot material described in any of the above embodiments.

In some embodiments, the light-emitting layer includes a first quantum dot film layer, a second quantum dot film layer and a third quantum dot film layer; the first quantum dot film layer, the second quantum dot film layer and the third quantum dot film layer are arranged in a first direction; the first direction is parallel to a plane where the light-emitting layer is located.

The light-emitting device further includes a first electrode film layer, a charge transport layer and a second electrode film layer; the first electrode film layer, the charge transport layer, the light-emitting layer and the second electrode film layer are arranged in sequence in a second direction; the second direction is perpendicular to the first direction.

In some embodiments, a first quantum dot material forming the first quantum dot film layer includes a cross-linking agent, and the cross-linking agent includes at least four diazonaphthoquinone units.

In some embodiments, the cross-linked quantum dot material is selected from any one of structures represented by following general formula II;

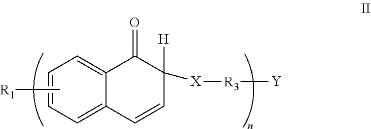

where X is selected from any one of single bonds, oxygen groups, imino groups, and ester groups; R₃ is selected from any one of —COO— containing C1-C40 carbon chains, —NH— containing C1-C40 carbon chains, —S— containing C1-C40 carbon chains, and organophosphorus compounds containing C1-C40 carbon chains; R₁ is selected from any one of substituted or unsubstituted alkanes, substituted or unsubstituted heterocyclic compounds, and substituted or unsubstituted aromatic hydrocarbons; a value of n is selected from an integer greater than or equal to 2; and Y represents the quantum dot body.

In some embodiments, the cross-linked quantum dot material is selected from any one of structures represented by following general formula II-A;

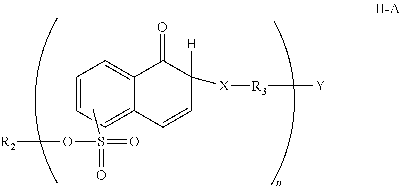

where R₂ is selected from any one of substituted or unsubstituted alkanes, substituted or unsubstituted heterocyclic compounds, and substituted or unsubstituted aromatic hydrocarbons.

In some embodiments, multiple cross-linked materials formed by the ligand material and the cross-linking agent are bonded to each quantum dot body; a cross-linked material is represented by a part of the structure shown in the general formula II-A excluding the quantum dot body.

In some embodiments, the light-emitting device further includes a sacrificial layer disposed between the charge transport layer and the light-emitting layer. The sacrificial layer includes a cross-linked body material, and a material for forming the cross-linked body material includes the cross-linking agent and a body material, and the cross-linking agent includes at least two diazonaphthoquinone units; each diazonaquinone unit of the at least two diazonaquinone units is configured to undergo a photochemical reaction under irradiation to generate a carbene intermediate.

The body material is bonded to the carbene intermediate through an addition reaction to form the cross-linked body material; or the carbene intermediate is configured to generate a unit containing a carboxyl group, and the body material is configured to be cross-linked through the carboxyl group to form the cross-linked body material. The charge transport layer includes any one of an electron transport layer and a hole transport layer.

In some embodiments, the light-emitting device further includes a sacrificial layer, and the sacrificial layer is disposed between the charge transport layer and the light-emitting layer. The sacrificial layer includes a cross-linked body material, and the cross-linked body material is selected from any one of structures represented by following general formula III;

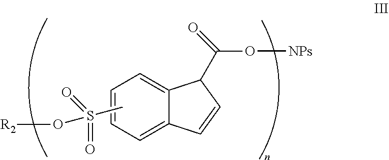

where R₂ is selected from any one of substituted or unsubstituted alkanes, substituted or unsubstituted heterocyclic compounds, and substituted or unsubstituted aromatic hydrocarbons; a value of n is selected from any one of 2, 3, 4, and 6; NPs represents a nanoparticle material; and multiple units each containing a carboxyl group formed by the cross-linking agent after irradiation are bonded to the NPs.

In some embodiments, the nanoparticle material includes any one of ZnO, ZnMgO, ZrO₂, TiO₂, HfO₂ and ITO.

In some embodiments, the light-emitting device further includes a sacrificial layer, and the sacrificial layer is disposed between the charge transport layer and the light-emitting layer. The sacrificial layer includes a cross-linked body material, and the cross-linked body material is selected from any one of structures represented by following general formula IV;

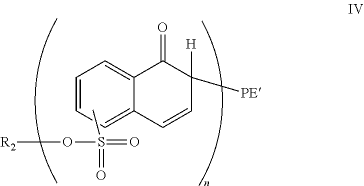

where R₂ is selected from any one of substituted or unsubstituted alkanes, substituted or unsubstituted heterocyclic compounds, and substituted or unsubstituted aromatic hydrocarbons; a value of n is selected from any one of 2, 3, 4, and 6; and PE′ represents a group formed by a hydrocarbon insertion addition reaction between an organic insulating material and the cross-linking agent.

In some embodiments, the organic insulating material is selected from any of polymethylmethacrylate and polyethyleneimine.

In some embodiments, the body material includes a nanoparticle material, and a mass of the cross-linking agent accounts for 0.5% to 10% of a mass of the nanoparticle material. Alternatively, the body material includes an organic insulating material, and a mass of the cross-linking agent accounts for 0.5% to 10% of a mass of the insulating material.

In yet another aspect, a manufacturing method for a light-emitting device is provided. The manufacturing method for the light-emitting device includes: forming a first electrode film layer on a substrate; forming a charge transport layer on a side of the first electrode film layer away from the substrate; and forming a sacrificial layer and a light-emitting layer on a side of the charge transport layer away from the first electrode film layer, the sacrificial layer being located between the charge transport layer and the light-emitting layer.

A material of the sacrificial layer includes any one of the structures represented by the general formula III. Alternatively, the material of the sacrificial layer includes any one of the structures represented by the general formula IV.

The light-emitting layer includes a first quantum dot film layer, a second quantum dot film layer and a third quantum dot film layer formed in sequence. The first quantum dot film layer, the second quantum dot film layer and the third quantum dot film layer are arranged in a first direction, and the first direction is parallel to a plane where the light-emitting layer is located. The first quantum dot film layer, the second quantum dot film layer and the third quantum dot film layer each include the cross-linked quantum dot material formed by the quantum dot material described in any of the above embodiments. The first quantum dot film layer, the second quantum dot film layer and the third quantum dot film layer are configured to emit light of different colors; the manufacturing method further includes: forming a second electrode film layer on a side of the light-emitting layer away from the sacrificial layer.

In some embodiments, the step of forming the sacrificial layer and the light-emitting layer on the side of the charge transport layer away from the first electrode film layer includes: spin-coating the side of the charge transport layer away from the first electrode film layer with a mixed material of a nanoparticle material and a cross-linking agent to form a first initial sacrificial layer; spin-coating a side of the first initial sacrificial layer away from the charge transport layer with a first quantum dot material, the first quantum dot material including a first quantum dot body, a ligand material and a cross-linking agent, so as to form a first initial quantum dot film layer; exposing the first initial sacrificial layer and the first initial quantum dot film layer; developing the first initial quantum dot film layer with a non-polar solvent to form the first quantum dot film layer; developing the first initial sacrificial layer with a polar solvent to form a first sacrificial layer;
spin-coating a side of the first quantum dot film layer away from the first sacrificial layer with a mixed material of a nanoparticle material and a cross-linking agent to form a second initial sacrificial layer; spin-coating a side of the second initial sacrificial layer away from the charge transport layer with a second quantum dot material, the second quantum dot material including a second quantum dot body, a ligand material and a cross-linking agent, so as to form a second initial quantum dot film layer; exposing the second initial quantum dot film layer and the second initial sacrificial layer; developing the second initial quantum dot film layer with a non-polar solvent to form the second quantum dot film layer; developing the second initial sacrificial layer with a polar solvent to form a second sacrificial layer,
spin-coating a side of the second quantum dot film layer away from the second sacrificial layer with a mixed material of a nanoparticle material and a cross-linking agent to form a third initial sacrificial layer; spin-coating a side of the third initial sacrificial layer away from the charge transport layer with a third quantum dot material, the third quantum dot material including a third quantum dot body, a ligand material and a cross-linking agent, so as to form a third initial quantum dot film layer; exposing the third initial quantum dot film layer and the third initial sacrificial layer; developing the third initial quantum dot film layer with a non-polar solvent to form the third quantum dot film layer; and developing the third initial sacrificial layer with a polar solvent to form a third sacrificial layer. The sacrificial layer includes the first sacrificial layer, the second sacrificial layer and the third sacrificial layer.

In some embodiments, the step of forming the sacrificial layer and the light-emitting layer on the side of the charge transport layer away from the first electrode film layer includes: spin-coating the side of the charge transport layer away from the first electrode film layer with a mixed material of an organic insulating material and a cross-linking agent to form a fourth initial sacrificial layer; spin-coating a side of the fourth initial sacrificial layer away from the charge transport layer with a first quantum dot material, the first quantum dot material including a first quantum dot body, a ligand material and a cross-linking agent, so as to form a first initial quantum dot film layer; exposing the fourth initial sacrificial layer and the first initial quantum dot film layer; developing the first initial quantum dot film layer and the fourth initial sacrificial layer with a non-polar solvent to form the first quantum dot film layer and a fourth sacrificial layer;
spin-coating a side of the first quantum dot film layer away from the fourth sacrificial layer with a mixed material of an organic insulating material and a cross-linking agent to form a fifth initial sacrificial layer; spin-coating a side of the fifth initial sacrificial layer away from the first quantum dot film layer with a second quantum dot material, the second quantum dot material including a second quantum dot body, a ligand material and a cross-linking agent, so as to form a second initial quantum dot film layer; exposing the fifth initial sacrificial layer and the second initial quantum dot film layer; developing the second initial quantum dot film layer and the fifth initial sacrificial layer with a non-polar solvent to form the second quantum dot film layer and a fifth sacrificial layer;
spin-coating a side of the second quantum dot film layer away from the fifth sacrificial layer with a mixed material of an organic insulating material and a cross-linking agent to form a sixth initial sacrificial layer; spin-coating a side of the sixth initial sacrificial layer away from the second quantum dot film layer with a third quantum dot material, the third quantum dot material including a third quantum dot body, a ligand material and a cross-linking agent, so as to form the third initial quantum dot film layer; exposing the sixth initial sacrificial layer and the third initial quantum dot film layer; and developing the third initial quantum dot film layer and the sixth initial sacrificial layer with a non-polar solvent to form the third quantum dot film layer and a sixth sacrificial layer. The sacrificial layer includes the fourth sacrificial layer, the fifth sacrificial layer and the sixth sacrificial layer.

In yet another aspect, a display apparatus is provided. The display apparatus includes the light-emitting device as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a process diagram of forming a cross-linked quantum dot material, in accordance with some embodiments of the present disclosure;

FIG. 2 is a structural diagram of a light-emitting device, in accordance with some embodiments of the present disclosure;

FIG. 3 is a structural diagram of a first quantum dot film layer, in accordance with some embodiments of the present disclosure;

FIG. 4 is another structural diagram of a light-emitting device, in accordance with some embodiments of the present disclosure;

FIG. 5 is a thickness curve diagram of a first quantum dot film layer, in accordance with some embodiments of the present disclosure;

FIG. 6 is another thickness curve diagram of a first quantum dot film layer, in accordance with some embodiments of the present disclosure;

FIG. 7 is a curve diagram showing current density and voltage of a light-emitting device, in accordance with some embodiments of the present disclosure;

FIG. 8 is a curve diagram showing luminance and voltage of a light-emitting device, in accordance with some embodiments of the present disclosure;

FIG. 9 is a curve diagram showing current efficiency and voltage of a light-emitting device, in accordance with some embodiments of the present disclosure;

FIG. 10 is an ultraviolet-visible light absorption spectrum diagram before and after development of a first quantum dot film layer, in accordance with some embodiments of the present disclosure;

FIG. 11 is yet another structural diagram of a light-emitting device, in accordance with some embodiments of the present disclosure;

FIG. 12 is a process diagram of forming a cross-linked body material based on a cross-linking agent and nanoparticles, in accordance with some embodiments of the present disclosure;

FIG. 13 is a flow diagram of a manufacturing method of a light-emitting device, in accordance with some embodiments of the present disclosure;

FIG. 14 is a diagram showing steps of a manufacturing method of a light-emitting device, in accordance with some embodiments of the present disclosure;

FIG. 15 is a flow diagram of a manufacturing method of a light-emitting layer and a sacrificial layer of a light-emitting device, in accordance with some embodiments of the present disclosure;

FIGS. 16 to 18 are diagrams showing steps of a manufacturing method of a light-emitting layer and a sacrificial layer of a light-emitting device, in accordance with some embodiments of the present disclosure;

FIG. 19 is another flow diagram of a manufacturing method of a light-emitting layer and a sacrificial layer of a light-emitting device, in accordance with some embodiments of the present disclosure;

FIGS. 20 to 22 are another diagrams showing steps of a manufacturing method of a light-emitting device, in accordance with some embodiments of the present disclosure;

FIG. 23 is a structural diagram of a display substrate, in accordance with some embodiments of the present disclosure; and

FIG. 24 is a structural diagram of a display apparatus, in accordance with some embodiments of the present disclosure.

### DETAILED DESCRIPTION

The technical solutions in some embodiments of the present disclosure will be described clearly and completely with reference to the accompanying drawings; obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, features defined by “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled”, “connected” and derivatives thereof may be used. For example, the term “connected” may be used in the description of some embodiments to indicate that two or more elements are in direct physical or electrical contact with each other. For another example, the term “coupled” may be used in the description of some embodiments to indicate that two or more elements are in direct physical or electrical contact. However, the term “coupled” or “communicatively coupled” may also mean that two or more elements are not in direct contact with each other, but still cooperate or interact with each other. The embodiments disclosed herein are not necessarily limited to the contents herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes the following three combinations: only A, only B, and a combination of A and B.

The term such as “about”, “substantially”, and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel”, “perpendicular”, or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views that are schematic illustrations of idealized embodiments. In the accompanying drawings, thickness of layers and sizes of regions may be exaggerated for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

Quantum dots light-emitting diode display (QLED) is a new display technology developed based on organic light-emitting display (OLED). The light-emitting layer used by QLED is a quantum dot layer. The principle is to inject holes into the quantum dot layer through the hole transport layer, inject electrons into the quantum dot layer through the electron transport layer, and the holes and electrons recombine in the quantum dot layer to achieve emission.

Compared with OLED, QLED has the advantages of high color saturation, wide color gamut, narrow luminescence peak, good stability and the like. With the in-depth development of quantum dot technology, research on quantum dot displays has become increasingly in-depth, and quantum efficiency has continued to improve, basically reaching the level of industrialization. It has become a future trend to further adopt new processes and technologies to achieve industrialization.

Photolithography has developed into a mature technology in integrated circuit processing, which may provide experience, lessons and reference for the development of the method of quantum dot photolithography pattering. Although the traditional photoresist method may realize the patterning of quantum dots, the further application of this method is restricted due to bottleneck issues such as complex and cumbersome process and poor solvent compatibility. In order to solve the above limitations, there is an urgent need to develop new quantum dot lithography patterning methods.

Based on this, embodiments of the present disclosure provide a quantum dot material. The quantum dot material includes a quantum dot body and a ligand material that is coordinately bonded to the quantum dot body. The quantum dot material further includes a cross-linking agent, and the cross-linking agent includes at least two diazonaphthoquinone units. Each diazonaphthoquinone unit of the at least two diazonaphthoquinone units is configured to undergo a photochemical reaction under irradiation to generate a carbene intermediate; the ligand material is configured to be bonded to the carbene intermediate through an addition reaction to form a cross-linked quantum dot material.

For example, the quantum dot body may be configured to emit any of red light, green light, or blue light.

For example, the ligand material is generally an organic material, and the ligand material is bonded to the quantum dot body through a coordination bond. The ligand material may fill the defects on the surface of the quantum dot body, thereby improving the stability and quantum yield of the quantum dot body. Moreover, common functional groups in the ligand material include amino (—NH₂), carboxyl (—COOH), and sulfhydryl (—SH).

A compound containing at least two diazonaphthoquinone units are used as the cross-linking agents, which is because the diazonaphthoquinone units may undergo an addition reaction with an alkyl carbon-hydrogen bond (—CH), a hydroxyl group (—OH), an amino group (—NH₂), a carboxyl group (—COOH) or a sulfhydryl group (—SH) in organic materials under light (ultraviolet light). The specific principles will be described below.

The reaction principle of diazonaphthoquinone under UV irradiation will be described below.

Diazonaphthoquinone and its derivatives can undergo photochemical reactions under ultraviolet light (UV) irradiation to produce nitrogen (N₂) and a carbene intermediate, as shown in the following formula.

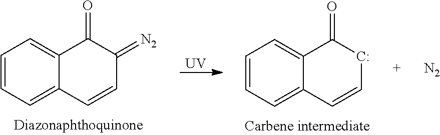

The carbene intermediate has high activity, so that the carbene intermediate will undergo further reactions quickly. The further reactions include the following two aspects, which are represented as a first aspect and a second aspect respectively.

First aspect: the carbene intermediate may undergo a chemical reaction (an addition reaction) with functional groups such as an alkyl carbon-hydrogen bond (—CH), hydroxyl group (—OH), amino group (—NH₂) or carboxyl group (—COOH).

For example, the carbene intermediate undergo a carbon-hydrogen insertion addition reaction with an alkyl carbon-hydrogen bond (—CH) that is in an organic material and the following chemical reaction formula for details.

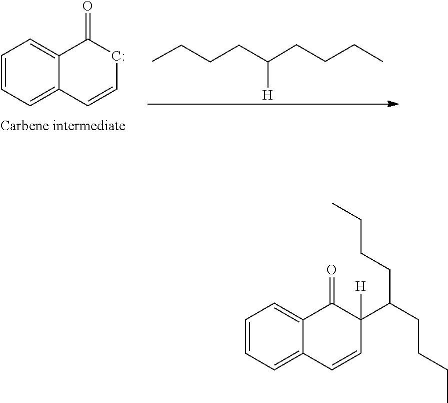

For example, the carbene intermediate undergo an addition reaction with a hydroxyl group (—OH) that is in an organic material to form ether compounds, and the following chemical reaction formula for details.

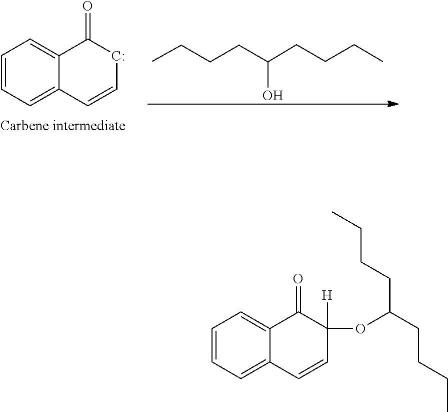

For example, the carbene intermediate may undergo a nitrogen-hydrogen insertion addition reaction with an amino group (—NH₂) that is in an organic material, and the following chemical reaction formula for details.

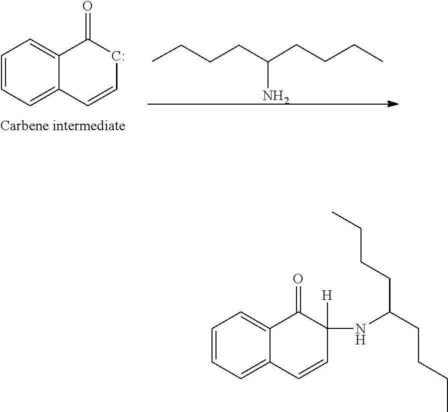

For example, the carbene intermediate may undergo an addition reaction with a carboxyl group (—COOH) that is in an organic material to form an ester compound, and the following chemical reaction formula for details.

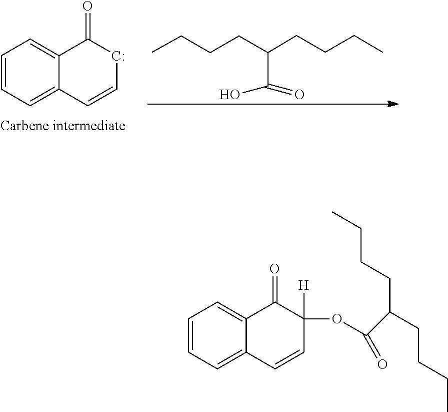

Second aspect: there is a carbonyl group at the ortho position of the carbene intermediate, and the carbene will undergo a wolf rearrangement reaction to form a structure containing ketene. Due to the accumulated double bonds in the ketene, the ketene has active chemical properties and may react with water in the environment to form a carboxyl group.

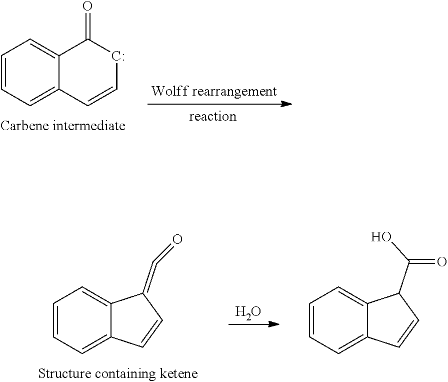

The reactions described in the above first and second aspects are carried out simultaneously and have a competitive relationship.

Moreover, diazonaphthoquinone may modify sulfonyl chloride on the carbon of the benzene ring. The sulfonyl chloride may undergo a nucleophilic substitution reaction with a hydroxyl functional group, so that different numbers of diazonaphthoquinone units may be linked to a molecular structure through a linker to form a cross-linking agent. The description for the linker is as follows and will not be repeated here.

Therefore, a compound containing at least two diazonaphthoquinone units may be used as a cross-linking agent, and the cross-linking agent may be added to the quantum dot material for forming the quantum dot film layer, and the diazonaphthoquinone units may undergo, under (ultraviolet (UV) light) irradiation, an addition reaction with the ligand material (organic material) on the quantum dot body to form a cross-linked quantum dot material with a network structure. The solubility of the cross-linked quantum dot material with a network structure in the developer is reduced to achieve direct patterning without photoresist of quantum dots. Thus, this method is simple and efficient, and it is possible to reduce the process flow of quantum dot film processing.

In some embodiments, the ligand material includes an alkyl carbon-hydrogen bond (—CH), and the alkyl carbon-hydrogen bond (—CH) of the ligand material is configured to be bonded to the carbene intermediate through a carbon-hydrogen insertion addition reaction. Alternatively, the ligand material includes a hydroxyl group (—OH), and the hydroxyl group (—OH) in the ligand material is configured to be bonded to the carbene intermediate through an addition reaction to form an ether compound. Alternatively, the ligand material includes an amino group (—NH₂), and the amino group (—NH₂) in the ligand material is configured to be bonded to the carbene intermediate through a nitrogen-hydrogen insertion addition reaction. Alternatively, the ligand material includes a carboxyl group (—COOH), and the carboxyl group (—COOH) in the ligand material is configured to be bonded to the carbene intermediate through an addition reaction to form an ester compound.

For example, the ligand material includes any one of oleic acid, oleylamine, isooctylthiol and octylthiol.

Regarding the addition reaction of the carbene intermediate formed by the alkyl carbon-hydrogen bond (—CH), hydroxyl group (—OH), amino group (—NH₂) or carboxyl group (—COOH) in the ligand material and the cross-linking agent, reference will be made to the above description, and will not be repeated here.

In some embodiments, the cross-linking agent is selected from any one of structures represented by the following general formula I.

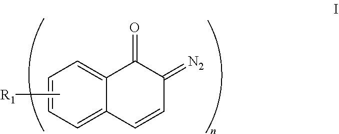

where R₁ is selected from any one of substituted or unsubstituted alkanes, substituted or unsubstituted heterocyclic compounds, and substituted or unsubstituted aromatic hydrocarbons, and the value of n is selected from an integer greater than or equal to 2.

It will be noted that n represents the number of corresponding groups, that is, the value of n represents the number of diazonaphthoquinone units in the cross-linking agent.

In other words, the cross-linking agent may be formed by linking at least two diazonaphthoquinone units to the R₁ group.

For example, the value of n is selected from any one of 2, 3, 4, 5 and 6. The cross-linking agent containing 2, 3, 4, 5 or 6 diazonaphthoquinone units is used because this type of cross-linking agent is convenient for synthesis while the purpose of forming a cross-linked quantum dot material with the ligand material in the quantum dot body is met.

In order to ensure that cross-linked quantum dot materials may be formed, each cross-linking agent molecule contains two or more diazonaphthoquinone units. In order to increase the degree of cross-linking and improve the stability of the cross-linked quantum dot material, each cross-linking agent molecule may contain more than two diazonaphthoquinone units. Considering the difficulty of synthesis of the cross-linking agent and steric hindrance effect, generally each cross-linking agent molecule contains no more than 6 diazonaphthoquinone units.

In some examples, the cross-linking agent is selected from any one of the structures represented by the following general formula I-A.

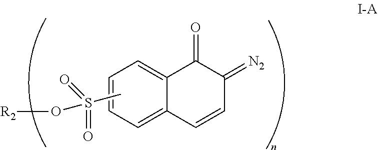

where R₂ is selected from any one of substituted or unsubstituted alkanes, substituted or unsubstituted heterocyclic compounds and substituted or unsubstituted aromatic hydrocarbons; a value of n is selected from an integer greater than or equal to 2.

That is, by modifying sulfonyl chloride (—SO₂Cl) on the benzene ring, sulfonyl chloride (—SO₂Cl) may undergo a nucleophilic substitution reaction with the functional group of hydroxyl (—OH), thereby linking different numbers of diazonaphthoquinone units to a molecular structure through a linker to form the cross-linking agent.

For example, a structure of the linker is first described, and the linker may be selected from any of the following structural formulas.

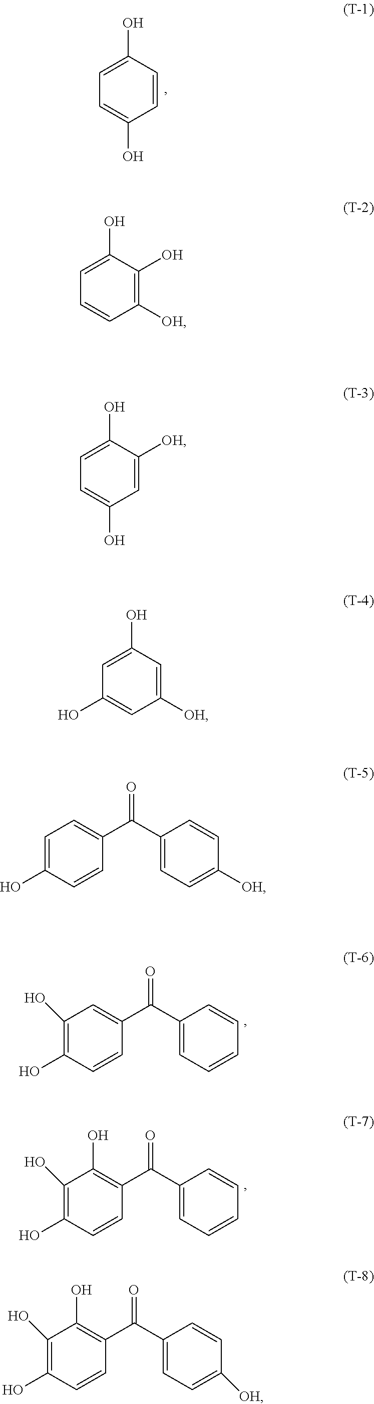

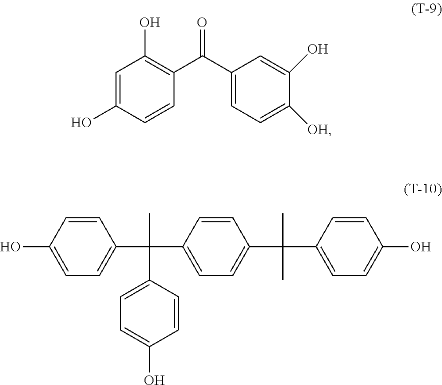 [SMILES: O=C(c1ccc(O)c(O)c1)c1ccc(O)cc1O ; CC(C)(c1ccc(O)cc1)c1ccc(C(C)(c2ccc(O)cc2)c2ccc(O)cc2)cc1]

It will be noted that the above structural formulas (T-1), (T-2), (T-3), (TA), (T-5), (T-6), (T-7), (T-8), (T-9) and (T-10) are examples of the structure of the linker, and are not limitations on the structure of the linker.

The above-mentioned linkers are all polyhydroxy compounds. These linkers may each undergo a nucleophilic substitution reaction with the sulfonyl chloride on the diazonaphthoquinone unit to obtain a cross-linking agent containing at least two diazonaphthoquinone units. Moreover, the presence of the linker allows the UV absorption of the formed cross-linking agent to cover a range from 250 nm to the visible light region.

The wide UV absorption range of the cross-linking agent may reduce the damage of UV light to the quantum dot body. The shorter the wavelength of ultraviolet light, the higher the energy of the ultraviolet light, which will cause great damage to the quantum dot body. Due to the existence of the linker, the UV absorption of the cross-linking agent may cover the range from 250 nm to the visible light region. During exposure, the cross-linking agent containing the above-mentioned linker effectively protects the quantum dot body to ensure the stability of the performance of the quantum dot body.

It can be understood that how many hydroxyl groups (—OH) contained in the linker means that how many diazonaphthoquinone units that may be bonded. In other words, the number of hydroxyl groups (—OH) in the linker is the same as the number of diazonaphthoquinone units in the formed cross-linking agent.

For example, the linkers represented by the structural formulas (T-1), (T-5) and (T-6) may each form a cross-linking agent containing 2 diazonaphthoquinone units; the linkers represented by the structural formulas (T-2), (T-3), (T-4), (T-7) and (T-10) may each form a cross-linking agent containing 3 diazonaphthoquinone units; the linkers represented by the structural formulas (T-8) and (T-9) may each form a cross-linking agent containing 4 diazonaphthoquinone units.

For example, the linker represented by the structural formula (T-10) undergoes an affinity substitution reaction with the sulfonyl chloride in the diazonaphthoquinone unit, and the chemical reaction formula for forming the cross-linking agent is as follows.

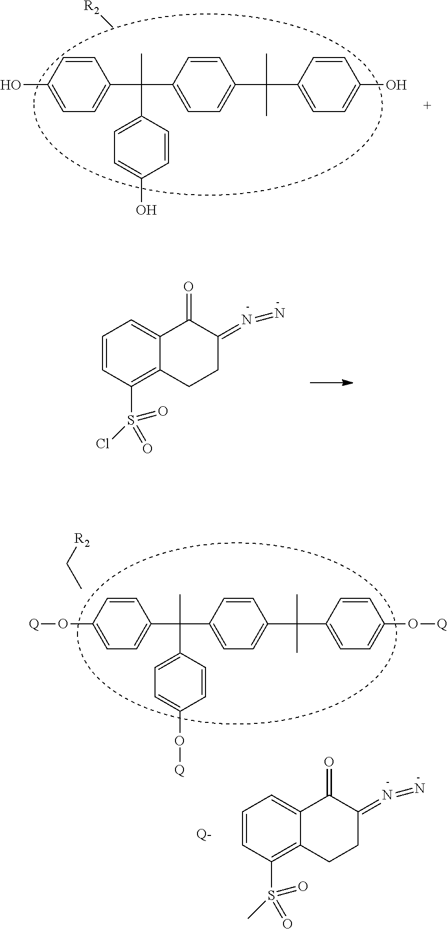

For example, based on the structure of the above linker, the structure of the formed cross-linking agent may be selected from any one of the following structural formulas.

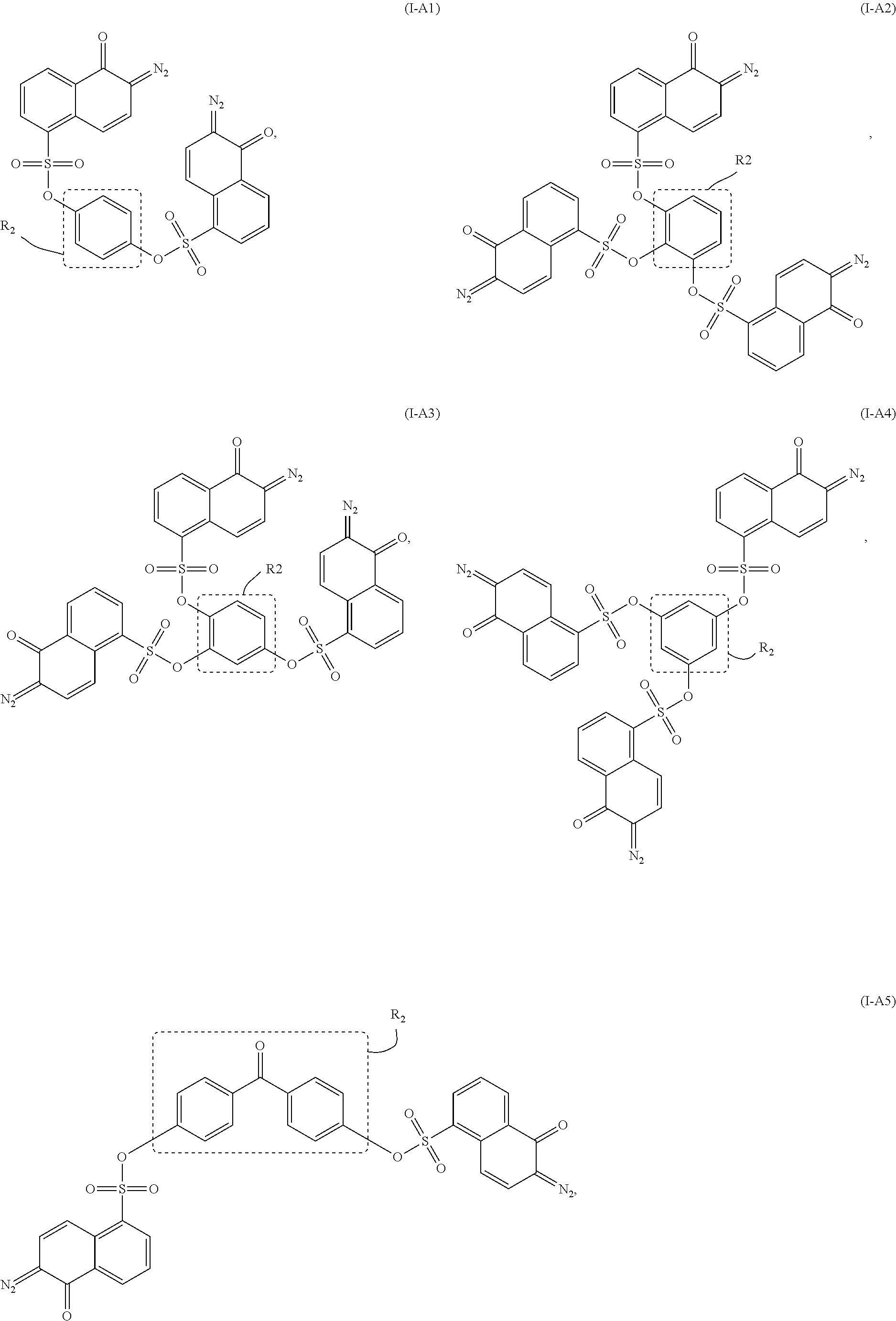

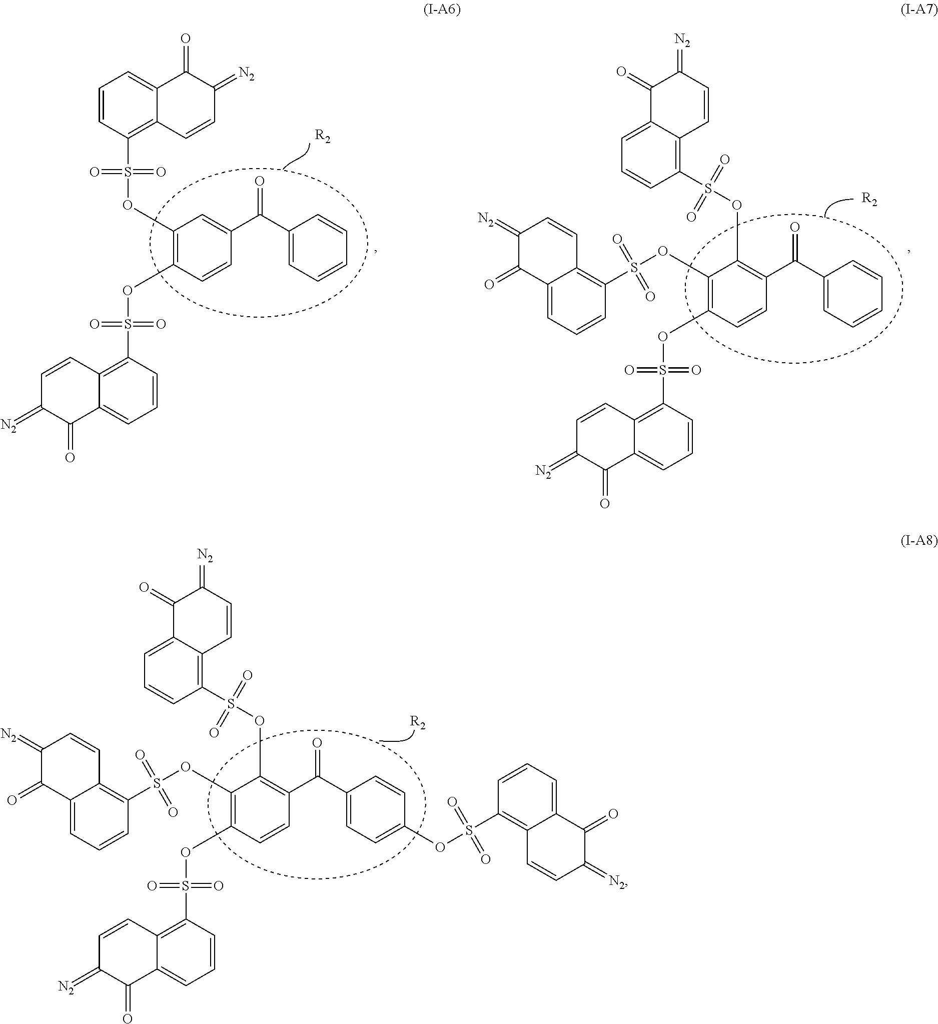

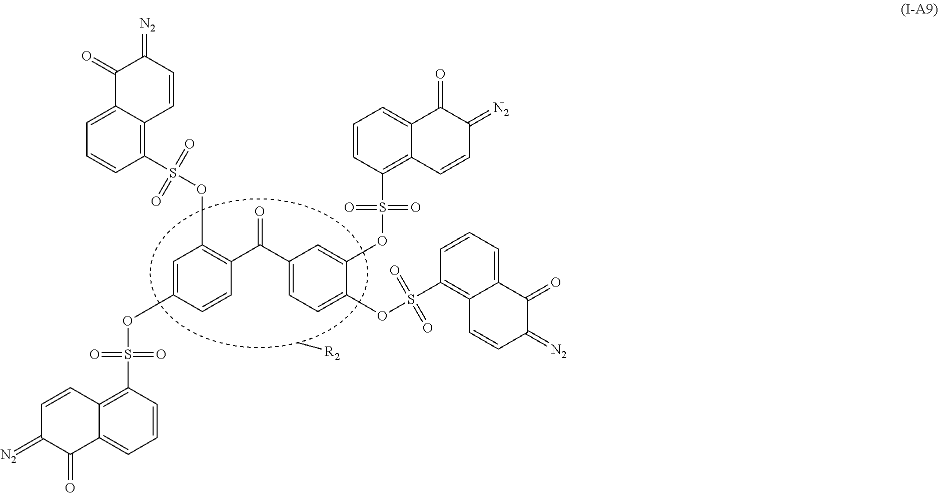

It should be noted that the above structural formulas (I-A1), (I-A2), (I-A3), (I-A4), (I-A5), (I-A6), (I-A7), (I-A8), and (I-A9) of the cross-linking agents are examples of the cross-linking agent structure, and are not limitations on the structure of the cross-linking agent.

In some examples, the mass of the cross-linking agent accounts for 5% to 10% of the mass of the quantum dot body.

For example, the mass of the cross-linking agent accounts for 5%, 6%, 7%, 8%, 9% or 10% of the mass of the quantum dot body, and there is no limit here.

The mass of the cross-linking agent accounts for 5% to 10% of the mass of the quantum dot body, which may meet the requirements of cross-linking the quantum dot material to form the cross-linked quantum dot material under light (ultraviolet (UV) light).

In some embodiments, the formed cross-linked quantum dot material is selected from any one of the structures shown in the following general formula II.

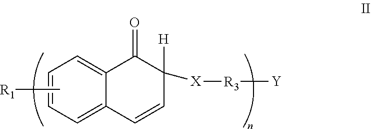

where X is selected from any one of single bonds, oxyl groups, amino groups, and ester groups; R₃ is selected from any one of —COO— containing C1-C40 carbon chains, —NH— containing C1-C40 carbon chains, —S— containing C1-C40 carbon chains, and organic phosphorus compounds containing C1-C40 carbon chains; R₁ is selected from any one of substituted or unsubstituted alkanes, substituted or unsubstituted heterocyclic compounds, and substituted or unsubstituted aromatic hydrocarbons; the value of n is selected from an integer greater than or equal to 2; Y represents the quantum dot body.

It will be noted that the carbon chain of Cm refers to a carbon chain containing m carbon (C) atoms.

R₃ may represent a group formed after the ligand material is coordinated with the quantum dot body and undergoes an addition reaction with the cross-linking agent.

For example, the ligand material adopts oleic acid (C₁₈H₃₄O₂), and the ligand material is bonded to the cross-linking agent through a hydrocarbon addition reaction. The structure of the formed cross-linked quantum dot material is shown in the following general formula II-1.

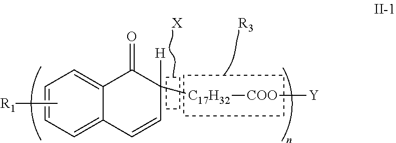

That is to say, in a case where the group in the ligand material that undergoes the addition reaction is an alkyl carbon-hydrogen bond (—CH), X represents a single bond; in a case where the group in the ligand material that undergoes the addition reaction is amino (—NH₂), X represents imino (—NH—); in a case where the group in the ligand material that undergoes the addition reaction is carboxyl (—COOH), X represents an ester group (—COO—); in a case where the group in the ligand material that undergoes the addition reaction is hydroxyl (—OH), X represents an oxyl group (—O—).

It will be noted that R₃ is selected from any one of —COO— containing C1-C40 carbon chains, —NH— containing C1-C40 carbon chains, —S— containing C1-C40 carbon chains and organic phosphorus containing C1-C40 carbon chains. In a case where R₃ is selected from —COO— containing C1-C40 carbon chains, —COO— is used to form a coordination bond with the quantum dot body. In a case where R₃ is selected from —NH— containing C1-C40 carbon chains, —NH— is used to form a coordination bond with the quantum dot body. In a case where R₃ is selected from —S— containing C1-C40 carbon chains, —S— is used to form a coordination bond with the quantum dot body. In a case where R₃ is selected from organic phosphorus compounds containing a C1-C40 carbon chain, the phosphorus atoms in the organic phosphorus compound are used to form a coordination bond with the quantum dot body.

In some examples, the formed cross-linked quantum dot material is selected from any one of the structures shown in the following general formula II-A.

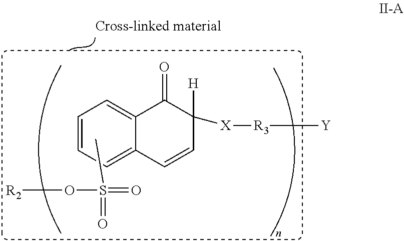

R₂ is selected from any one of substituted or unsubstituted alkanes, substituted or unsubstituted heterocyclic compounds, and substituted or unsubstituted aromatic hydrocarbons.

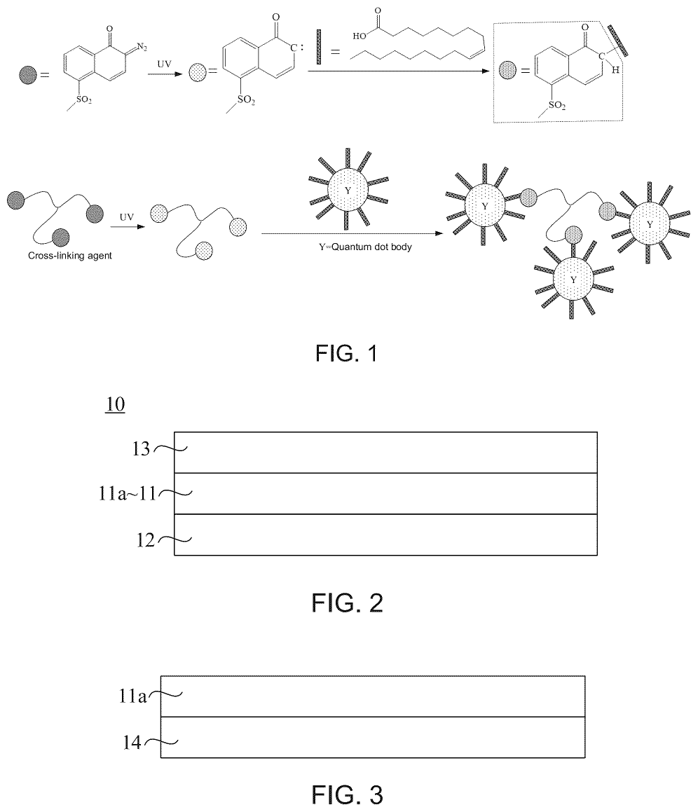

For the description of X, R₂ and R₃, reference will be made to the above content, which will not be repeated here. That is, a cross-linking agent is obtained through a nucleophilic substitution reaction between a compound containing polyhydroxyl groups and the sulfonyl chloride on the diazonaphthoquinone unit. The cross-linking agent undergoes an addition reaction with the ligand material on the quantum dot body to obtain a cross-linked quantum dot material. Considering an example in which the ligand material is oleic acid, the process of forming cross-linked quantum dot materials is shown in FIG. 1.

It will be noted that the structure of the cross-linked quantum dot material will be described by taking an example in which, for the quantum dot body in the structure shown in the general formula II-A, only one ligand material molecule is bonded to the quantum dot body. However, in the actual reaction process, multiple ligand material molecules are bonded to each quantum dot body. Then, a cross-linked material, formed by the multiple ligand materials and a cross-linking agent, is bonded to each quantum dot body, and the cross-linked material is expressed as the part of the structure shown in the general formula II-A excluding the quantum dot body. The structure shown in the cross-linked material may be referred to the general formula II-A.

In this way, multiple ligand materials will be bonded to each quantum dot body through the cross-linked material, so as to form a cross-linked quantum dot material with a network structure.

The solubility of cross-linked quantum dot material in a non-polar solvent is less than the solubility of the quantum dot material in the non-polar solvent.

Therefore, the above polysubstituted diazonaphthoquinone is selected as the cross-linking agent. Under light (UV) conditions, in the exposure area, a chemistry cross-linking reaction (addition reaction) occurs between the ligand material and the cross-linking agent that are coordinately bonded to the quantum dot body, and the solubility of the formed cross-linked quantum dot material in a non-polar solvent is reduced; in the non-exposed areas, there is no change in the quantum dot material. When developing with the non-polar solvent, the quantum dot material in the non-exposed area dissolves and may be developed to be removed, and the solubility of the cross-linked quantum dot material in the exposed area is reduced and the cross-linked quantum dot material in the exposed area is retained to form a pattered quantum dot film layer, thereby achieving the purpose of forming a quantum dot film layer by means of direct patterning.

In some examples, the non-polar solvent includes any of octane, toluene, and xylene.

For example, any one of octane, toluene, and xylene may be used as a solvent for quantum dot materials and as a developer.

Some embodiments of the present disclosure provide a light-emitting device 10. As shown in FIG. 2, the light-emitting device 10 includes a light-emitting layer 11. The light-emitting layer 11 includes the cross-linked quantum dot material formed by the quantum dot material described in any of the above embodiments.

Exemplarily, the light-emitting layer 11 includes a first quantum dot film layer 11a, and the first quantum dot film layer 11a is configured to emit red light.

For example, as shown in FIG. 3, in order to verify whether the cross-linked quantum dot material formed by the above quantum dot material may be used to form the patterned first quantum dot film layer 11a, and determine the performance of the formed patterned first quantum dot film layer 11a, verifications will be made as follows. The process of forming the cross-linked quantum dot material by using the above quantum dot material is as follows.

The quantum dot material includes: a first quantum dot body, a ligand material that is coordinately bonded to the first quantum dot body, and a cross-linking agent. For example, the first quantum dot body is a red quantum dot body, and the ligand material is an oleic acid ligand. The quantum dot material is dissolved in the solvent of toluene, and the concentration of the quantum dot material is 15 mg/mL. The substrate 14 is coated with the above quantum dot material under conditions of 2000 rpm and 30 seconds.

Then, the coating film is placed under the mask and is exposed with a mercury lamp (UV) for 30 s (the total dose is approximately 100 mJ/cm²).

Finally, the exposed coating film is immersed in a non-polar solution to be eluted and developed, and dried to obtain the patterned first quantum dot film layer 11a.

Using a fluorescence microscope to observe the effect of the patterned first quantum dot film layer 11a, uniform and stable red quantum dot pixels arranged in an array can be seen.

Using an electron microscope to observe the effect of the patterned first quantum dot film layer 11a, uniform and stable red quantum dot pixels arranged in an array can also be seen.

Therefore, the cross-linked quantum dot material formed by using the above quantum dot material, and under irradiation may be retained during development to form a pattern to obtain the patterned first quantum dot film layer 11a.

Moreover, the patterned quantum dot film may be obtained on different substrates. For example, the substrate 14 may be any one of a glass substrate, a silicon wafer substrate, a Sol-Gel (S-G) ZnO substrate, and a Sputter ZnO substrate.

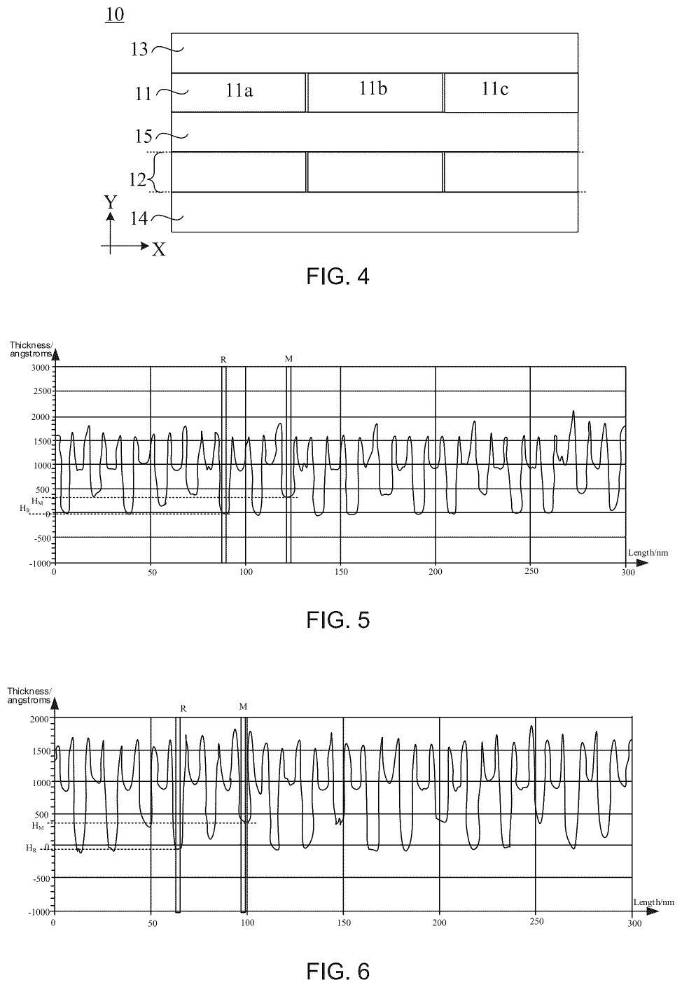

It should be noted that, as shown in FIG. 4, the quantum dot film layer includes any one of a first quantum dot film layer 11a, a second quantum dot film layer 11b, and a third quantum dot film layer 11c.

The performance of the patterned first quantum dot film layer 11a will be tested below.

Through the step experiments, the thickness of the first quantum dot film layer 11a is tested. As shown in FIGS. 5 and 6, FIGS. 5 and 6 are test diagrams of different samples. In FIGS. 5 and 6, the abscissa represents an extension dimension of the film layer in a direction parallel to a plane where the film layer is located, and the ordinate represents the thickness of the film layer.

The curve in the figure may be understood as a trend curve of a surface of the exposed film of the light-emitting device 10 after the first quantum dot film layer 11a is formed; for example, the exposed film layer includes: a surface of the pixel definition layer, a surface of the first quantum dot film layer 11a and a surface of the exposed film after the first quantum dot film layer 11a is removed by development. The position of the curve at the mark R and the lowest end of the curve represents a depth of the surface of the exposed film layer after removing the first quantum dot film layer 11a by development, and the size of the depth on the ordinate is denoted by HR. The position of the curve at the mark M and the lowest end of the curve represents a depth of the surface of the first quantum dot film layer 11a retained after development, and the size of the depth on the ordinate is denoted as HM.

It can be understood that the depth difference between HR and HM is the thickness of the first quantum dot film layer 11a. It can be seen from FIGS. 5 and 6 that the thickness of the first quantum dot film layer 11a is approximately 300 angstroms to 400 angstroms.

For example, as shown in FIG. 2, the light-emitting device 10 further includes a first electrode film layer 12 and a second electrode film layer 13, and the first quantum dot film layer 11a is disposed between the first electrode film layer 12 and the second electrode film layer 13. The efficiency of the light-emitting device 10 is further tested.

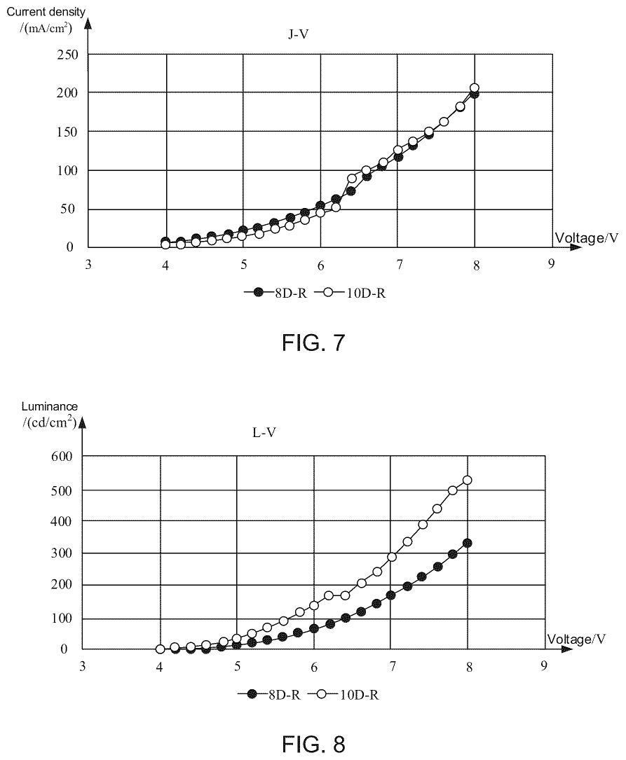

As shown in FIG. 7, which is a curve diagram (J-V) showing current density and voltage of the light-emitting device 10, in which the abscissa represents the voltage, and the ordinate represents the current density.

As shown in FIG. 8, which is a curve diagram (L-V) showing luminance and voltage of the light-emitting device 10, in which the abscissa represents the voltage, and the ordinate represents the luminance.

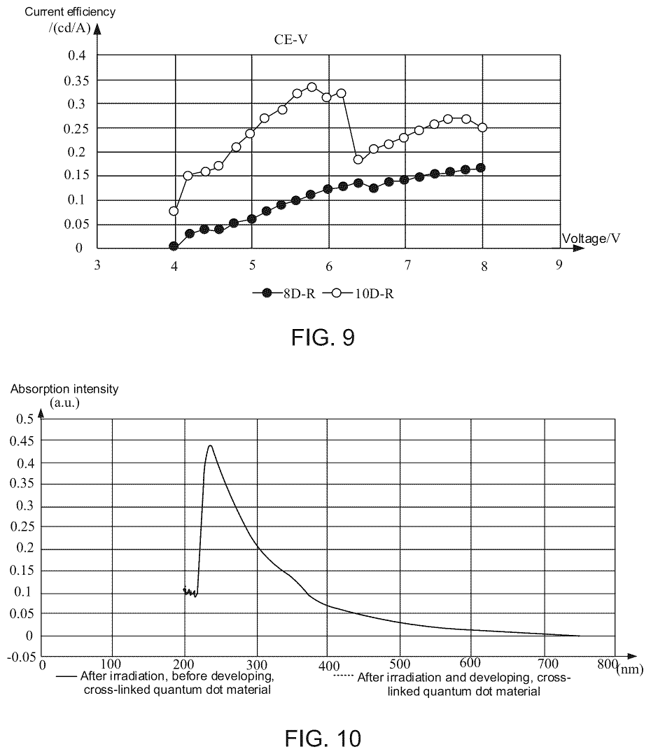

As shown in FIG. 9, which is a curve diagram (CE-V) showing current efficiency and voltage of the light-emitting device 10, in which the abscissa represents the voltage, and the ordinate represents the current efficiency.

Moreover, the two curves in FIGS. 7 to 9 represent the results of testing two samples, which are denoted as 8D-R and 10D-R respectively. It should be noted that the above two samples are the first quantum dot film layer 11a formed of the quantum dot material provided by the embodiments of the present disclosure, and the structure of the first quantum dot film layer 11a is shown in FIG. 2. In addition, samples 8D-R and 10D-R are samples from different batches. It can be seen from FIGS. 7 to 9 that there is a difference between the curve diagram (J-V) of current density and voltage, the curve diagram (L-V) of luminance and voltage, and the curve diagram (CE-V) of current efficiency and voltage of the two samples, which is caused by the fluctuating nature of the experiments. It can be seen from FIGS. 7 to 9 that the light-emitting device 10 formed of the quantum dot material in the embodiments of the present disclosure by means of direct patterning has good efficiency.

In order to explore the residual film rate of a cross-linked quantum dot material formed by a cross-linking agent containing at least two diazonaphthoquinone units, an oleic acid ligand and a first quantum dot body (e.g., a red quantum dot body), the quantum dot material is coated (2000 rpm, 30 s, 15 mg/mL), and is fully exposed using a mercury lamp (ultraviolet light) to form a film of cross-linked quantum dot material.

First, the UV-visible light absorption spectrum of the formed film is tested, as shown in FIG. 10. Then, the fully exposed film is immersed in a non-polar solution for elution and development, and the UV-visible light absorption spectrum of the film is tested again. It can be seen from FIG. 10 that the absorption intensity curves of the film formed by the cross-linked quantum dot material before and after development almost overlap, indicating that the cross-linked quantum dot material formed by the cross-linking agent containing at least two diazonaphthoquinone units, and the oleic acid ligand and the first quantum dot body has a high residual film rate.

Moreover, by comparing the first exciton absorption peak of the film before and after development (the first exciton absorption peak of the film is around 600 nm), it can be found that there is no change in the first exciton absorption peak of the film before and after development, further indicating that the cross-linked quantum dot material formed by the cross-linking agent containing at least two diazonaphthoquinone units after exposure has a high residual film rate and a good residual film effect.

Therefore, using the quantum dot material provided by the embodiments of the present disclosure, the quantum dot material may be directly spin-coated, exposed, and developed to obtain the patterned light-emitting layer 11, which avoid the step of removing glue in the traditional photolithography method, so that the manufacturing method is simple.

The structure of the light-emitting device 10 in which the light-emitting layer 11 of the light-emitting device 10 includes a plurality of quantum dot film layers will be described below.

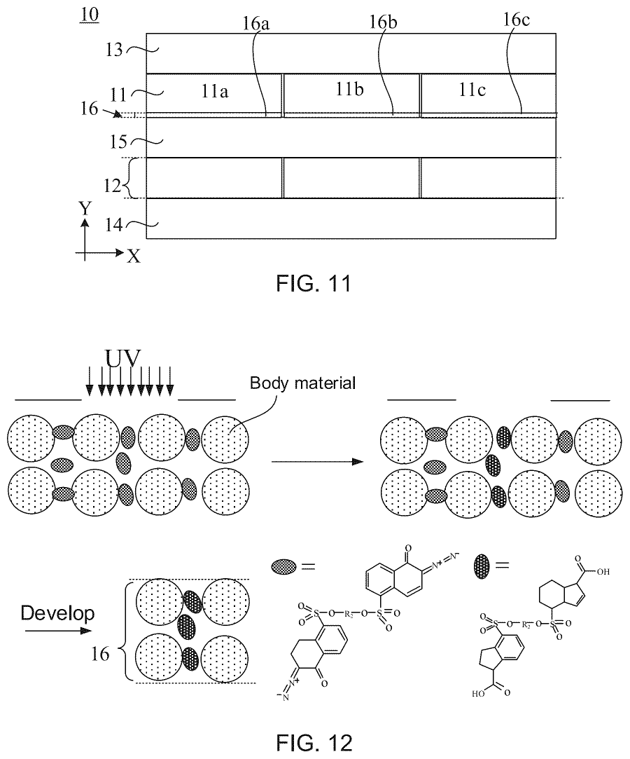

In some embodiments, as shown in FIGS. 4 and 11, the light-emitting layer 11 includes a first quantum dot film layer 11a, a second quantum dot film layer 11b and a third quantum dot film layer 11c. The first quantum dot film layer 11a, the second quantum dot film layer 11b and the third quantum dot film layer 11c are arranged in the first direction X, and the first direction X is parallel to a plane where the light-emitting layer 11 is located.

For example, the first quantum dot film layer 11a is configured to emit red light, the second quantum dot film layer 11b is configured to emit blue light, and the third quantum dot film layer 11c is configured to emit green light.

The light-emitting device 10 further includes a first electrode film layer 12, a charge transport layer 15 and a second electrode film layer 13. The first electrode film layer 12, the charge transport layer 15, the light-emitting layer 11 and the second electrode film layer 13 are arranged in sequence in a second direction Y, and the second direction Y is perpendicular to the first direction X.

For example, the first electrode film layer 12 is one of the anode and the cathode, and the second electrode film layer 13 is the other of the anode and the cathode.

For example, the charge transport layer 15 is one of an electron transport layer and a hole transport layer.

In a case where the first electrode film layer 12 is an anode, the charge transport layer 15 is a hole transport layer, and the second electrode film layer 13 is a cathode, and in this case, the light-emitting device 10 is an upright light-emitting device.

In a case where the first electrode film layer 12 is a cathode, the charge transport layer 15 is an electron transport layer, and the second electrode film layer 13 is an anode, and in this case, the light-emitting device 10 is an inverted light-emitting device.

In a case where the light-emitting layer 11 includes a plurality of quantum dot film layers arranged in the first direction X. For example, as shown in FIG. 11, the plurality of quantum dot film layers include a first quantum dot film layer 11a, a second quantum dot film layer 11b and a third quantum dot film layer 11c. In some examples, when the first quantum dot film layer 11a is formed, a small amount of the quantum dot material forming the first quantum dot film layer 11a will remain in the area where the second quantum dot film layer 11b and the third quantum dot film layer 11c are to be formed.

This is because there is a strong force between the quantum dot material forming the first quantum dot film layer 11a and the charge transport layer 15, and it is difficult to completely develop the quantum dot material in the unexposed area during development with the developer. Thus, it is possible to reduce the color gamut of the quantum dot body, cause the problem of cross-color, and weaken the advantages of the quantum dot body as an electroluminescent device. Therefore, it is necessary to solve the problem of the first quantum dot film layer 11a remaining in other pixel areas.

In some examples, a first quantum dot material forming the first quantum dot film layer 11a includes a cross-linking agent, and the cross-linking agent includes at least four diazonaphthoquinone units.

The cross-linking agent contains more diazonaphthoquinone units, which may increase the cross-linking sites to improve the cross-linking efficiency between the cross-linking agent and the ligand material on the quantum dot body, thereby improving the stability of the film layer formed by the cross-linked quantum dot material. The development process is performed by using a powerful developer (e.g., surfactant), so as to remove the residual first quantum dot materials in other pixel areas. Furthermore, it is possible to ameliorate the damage to the patterned first quantum dot film layer 11a formed by the cross-linked quantum dot material in the exposed area.

In some embodiments, the cross-linked quantum dot material is selected from any one of the structures shown in the following general formula II.

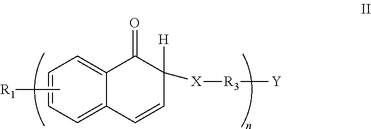

where X is selected from any one of single bonds, oxyl groups, amino groups, or ester groups; R₃ is selected from any one of —COO— containing C1-C40 carbon chains, —NH— containing C1-C40 carbon chains, —S— containing C1-C40 carbon chains, and organic phosphorus compounds containing C1-C40 carbon chains; R₁ is selected from any one of substituted or unsubstituted alkanes, substituted or unsubstituted heterocyclic compounds, and substituted or unsubstituted aromatic hydrocarbons; the value of n is selected from an integer greater than or equal to 2; Y represents the quantum dot body.

In some examples, the cross-linked quantum dot material is selected from any one of the structures represented by the following general formula II-A.

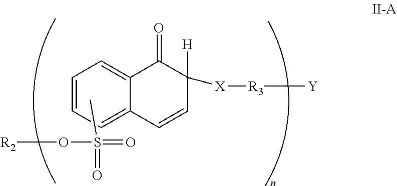

where R₂ is selected from any one of substituted or unsubstituted alkanes, substituted or unsubstituted heterocyclic compounds and substituted or unsubstituted aromatic hydrocarbons.

For the description of the general formula II-A, reference will be made to the above content and will not be repeated here.

In some other embodiments, in order to solve the problem of the first quantum dot film layer 11a remaining in other pixel areas, as shown in FIG. 11, the light-emitting device 10 further includes a sacrificial layer 16, and the sacrificial layer 16 is disposed between the charge transport layer 15 and light-emitting layer 11. The material of the sacrificial layer 16 includes a cross-linked body material. The material for forming the cross-linked body material includes a cross-linking agent and a body material. The cross-linking agent includes at least two diazonaphthoquinone units, and each diazonaphthoquinone unit of the at least two diazonaphthoquinone units is configured to undergo a photochemical reaction under irradiation to generate a carbene intermediate.

The body material is bonded to the carbene intermediate through an addition reaction to form a cross-linked body material. Alternatively, the carbene intermediate generates a unit containing a carboxyl group, and the body material is cross-linked through the carboxyl group to form a cross-linked bulk material. The charge transport layer 15 includes any one of an electron transport layer and a hole transport layer.

For example, the first electrode film layer 12 is an anode, the charge transport layer 15 is a hole transport layer, and the second electrode film layer 13 is a cathode. In this case, the light-emitting device 10 is an upright light-emitting device. The sacrificial layer 16 is disposed between the hole transport layer and the light-emitting layer 11.

For example, the first electrode film layer 12 is a cathode, the charge transport layer 15 is an electron transport layer, and the second electrode film layer 13 is an anode. In this case, the light-emitting device 10 is an inverted light-emitting device. The sacrificial layer 16 is disposed between the electron transport layer and the light-emitting layer 11.

The material of the sacrificial layer 16 includes a cross-linked body material formed by a cross-linking agent containing at least two diazonaphthoquinone units and a body material through a photochemical reaction. The solubility of the cross-linked body material in the solvent is less than the solubility of the cross-linking agent and body material. Therefore, as shown in FIG. 11, the sacrificial layer 16 may be formed by direct patterning. For the material forming the sacrificial layer 16, i.e., the cross-linking agent containing at least two diazonaphthoquinone units and the body material, compared with the quantum dot material, there is a weaker connection between the material forming the sacrificial layer 16 and the charge transport layer 15, so that the residual quantum dot material may be eluted and removed together with the material forming the sacrificial layer 16. As a result, it is possible to effectively avoid the residue of the quantum dot material to avoid the interference of the problem of cross-color.

The structure of the material of the sacrificial layer 16 will be described in detail below.

In some embodiments, the light-emitting device 10 includes a sacrificial layer 16. The sacrificial layer 16 includes a cross-linked body material, and the cross-linked body material is selected from any one of the structures shown in the following general formula III.

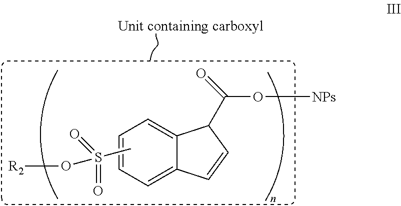

where R₂ is selected from any one of substituted or unsubstituted alkanes, substituted or unsubstituted heterocyclic compounds, and substituted or unsubstituted aromatic hydrocarbons; the value of n is selected from any of 2, 3, 4, 5 and 6; NPs represents a nanoparticle material. Moreover, multiple units each containing a carboxyl group formed by the cross-linking agent after irradiation are bonded to the NPs.

For the description of R₂ and n, reference may be made to the above content, which will not be repeated here.

Under irradiation, the cross-linking agent and the nanoparticle material may form a cross-linked body material with a network structure, which is based on the second aspect of the analysis of the principle that diazonaphthoquinone and its derivatives can be used as the cross-linking agent. That is, diazonaphthoquinone and its derivatives can undergo a photochemical reaction under ultraviolet (UV) irradiation to generate nitrogen (N₂) and a carbene intermediate. There is a carbonyl group at the ortho position of the carbene intermediate, and the carbene will undergo a wolff rearrangement reaction to form a structure containing ketene. Due to the accumulated double bonds in the ketene, the ketene has active chemical properties and may react with water in the environment to form a carboxyl group.

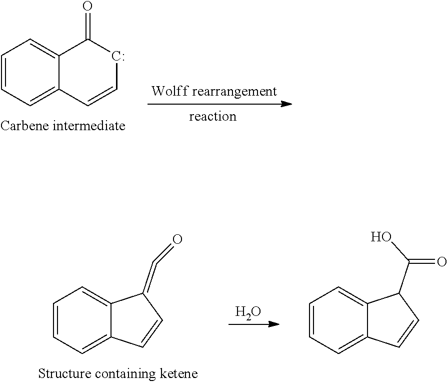

The carboxyl group may be bonded to the nanoparticle material through a coordination bond, and multiple units containing carboxyl may be bonded to each particle of the nanoparticle material. Therefore, by using a diazonaphthoquinone derivative containing at least two diazonaphthoquinone units as a cross-linking agent, and the cross-linking agent and the nanoparticle material may form a cross-linked body material with a network structure under (ultraviolet light (UV)) irradiation.

As shown in FIG. 12, for a spin coating solution formed by a mixed solution of the cross-linking agent and the nanoparticle material, there is a weak bonding force between the cross-linking agent containing at least two diazonaphthoquinone units and the nanoparticle material before irradiation, while there is a strong bonding force between the carboxyl group and the nanoparticle material after irradiation. When performing the development process with a polar solvent, the cross-linking agent and nanoparticle material in the unexposed area are eluted; in the exposed area, the cross-linked body material with the network structure has a low solubility in the polar solvent developer, and the sacrificial layer 16 may be formed by means of direct patterning.

Therefore, when developing the sacrificial layer 16, the residual quantum dot material may be removed to eliminate the influence of the residual quantum dot material on the pixels in other pixel areas, i.e., to avoid the influence of the quantum dot film layer formed first on the quantum dot film layer to be formed in the next other area, so as to solve the problem of cross-color.

As an example, the reaction formula in which the cross-linking agent undergoes a chemical reaction according to the mechanism described in the second aspect is as follows.

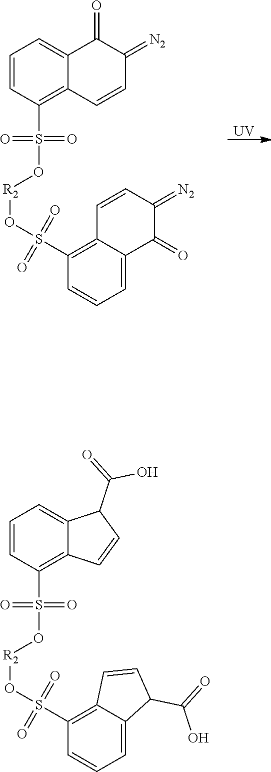

The carboxyl group in the above reaction formula will be bonded to the nanoparticle material through a coordination bond to form the cross-linked body material.

It will be noted that the above is an example of the chemical reaction based on the cross-linking agent containing 2 diazonaphthoquinone units. The cross-linking agent containing 3 diazonaphthoquinone units or 4 diazonaphthoquinone units all satisfies the requirements. For the description of the structural formula of the cross-linking agent, reference will be made to the description of the structure shown in the general formula I-A, which will not be repeated here.

For example, the nanoparticle material includes any one of ZnO, ZnMgO, ZrO₂, TiO₂, HfO₂ and ITO. The sacrificial layer 16 is formed of any material among ZnO, ZnMgO, ZrO₂, TiO₂, HfO₂ and ITO. In this case, the charge transport layer 15 is an electron transport layer. For example, ZnO nanoparticles may be used to form the electron transport layer.

For example, the body material includes the nanoparticle material, and the mass of the cross-linking agent accounts for 0.5% to 10% of the mass of the nanoparticle material.

For example, the mass of the cross-linking agent accounts for 0.5%, 2%, 4%, 5%, 7%, 8%, 9% or 10% of the mass of the nanoparticle material, which is not limited here.

By setting the mass of the cross-linking agent to account for 0.5% to 10% of the mass of the nanoparticle material, it is possible to meet the requirements for forming the cross-linked body material

In some embodiments, the light-emitting device 10 includes a sacrificial layer 16. The sacrificial layer 16 includes a cross-linked body material, and the cross-linked body material is selected from any one of the structures represented by the following general formula IV.

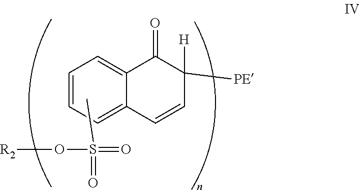

where R₂ is selected from any one of substituted or unsubstituted alkanes, substituted or unsubstituted heterocyclic compounds, and substituted or unsubstituted aromatic hydrocarbons; the value of n is selected from any of 2, 3, 4, 5 and 6; PE′ represents a group formed by a hydrocarbon insertion addition reaction between an organic insulating material and the cross-linking agent.

For the description of R₂ and n, reference will be made to the above content and will not be repeated here.

Under irradiation, the cross-linking agent and the organic insulating material may form a cross-linked body material with a network structure, which is based on the description, in the first aspect, to the principle that diazonaphthoquinone and its derivatives can be used as the cross-linking agent. Diazonaphthoquinone and its derivatives can undergo photochemical reactions under ultraviolet (UV) irradiation to generate a carbene intermediate, and the carbene intermediate can undergo a chemical reaction (addition reaction) with an alkyl carbon-hydrogen bond (—CH), hydroxyl (—OH), amino (NH₂), carboxyl (—COOH) or other functional groups.

The alkyl carbon-hydrogen bond (—CH) must exist in the organic insulating material. Therefore, the cross-linking agent may be bonded to the organic insulating material through a hydrocarbon insertion addition reaction to form a cross-linked body material.

For example, the reaction process in which the cross-linking agent may be bonded to the organic insulating material through a hydrocarbon insertion addition reaction is as shown in the following formula.

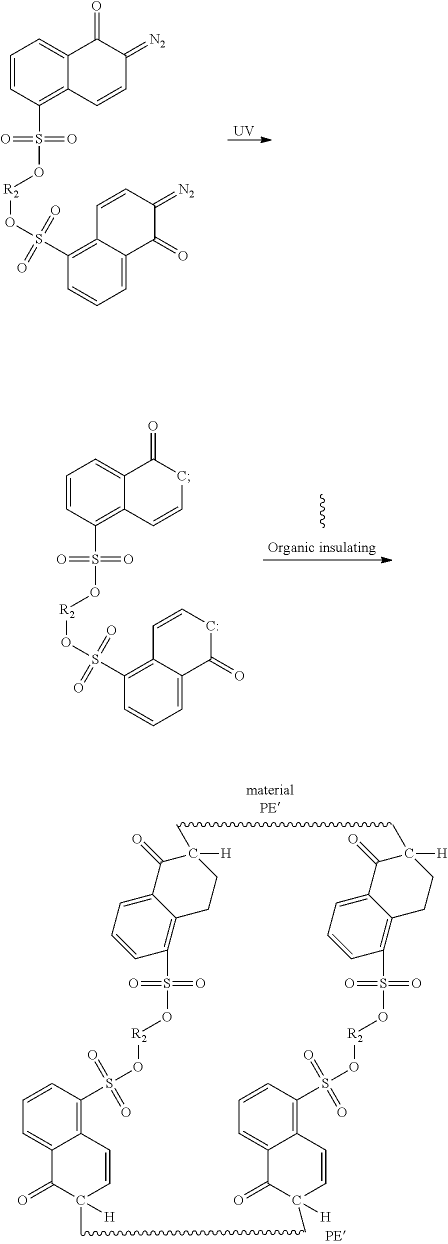

It will be noted that regarding the structure of R₂, reference may be made to the above description and will not be repeated here. Moreover, the above is an example of a chemical reaction based on the cross-linking agent containing 2 diazonaphthoquinone units. The cross-linking agent contains 3 diazonaphthoquinone units or 4 diazonaphthoquinone units, which meet the requirements. As for the description of the structural formula of the cross-linking agent, reference will be made to the description of the structure shown in the general formula I-A, and will not be repeated here.

For a spin coating solution formed by a mixed solution of the cross-linking agent and the organic insulating material, the carbene intermediate present in the cross-linking agent and the alkyl carbon-hydrogen bond (—CH) in the organic insulating material undergo an insertion addition reaction after irradiation, forming the cross-linked body material with the structure shown in general formula IV.

When developing with a non-polar solvent, the solubility of the cross-linked body material in the exposed area is reduced and the cross-linked body material in the exposed area is retained, while the cross-linking agent and organic insulating material in the non-exposed area are eluted. Thus, the sacrificial layer 16 is formed by means of direct patterning. When the cross-linking agent and organic insulating material in the non-exposed area are eluted, the residual quantum dot material is removed, which may eliminate the influence of the residual quantum dot material on the pixels in other pixel areas, i.e., avoid the influence of the quantum dot film layer formed first on the quantum dot film layer to be formed in the next other areas to solve the problem of cross-color.

For example, the organic insulating material is selected from polymethylmethacrylate and polyethyleneimine.

Any of polymethylmethacrylate and polyethyleneimine contains an alkyl carbon-hydrogen bond (—CH). Moreover, the organic insulating material is disposed between the electron transport layer and the light-emitting layer 11, which is beneficial to balancing the transmission efficiency of electrons and charges, thereby improving the efficiency of the light-emitting device 10.

For example, the body material includes an organic insulating material, and the mass of the cross-linking agent accounts for 0.5% to 10% of the mass of the organic insulating material.

For example, the mass of the cross-linking agent accounts for 0.5%, 1%, 3%, 5%, 6%, 8%, 9% or 10% of the mass of the organic insulating material, which is not limited here.

By setting the mass of the cross-linking agent to account for 0.5% to 10% of the mass of the organic insulating material, it is possible to meet the requirements for forming the cross-linked body material.

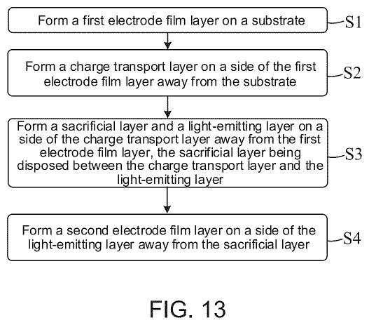

Some embodiments of the present disclosure provide a manufacturing method for a light-emitting device, as shown in FIG. 13, the manufacturing method for the light-emitting device includes steps S1 to S4.

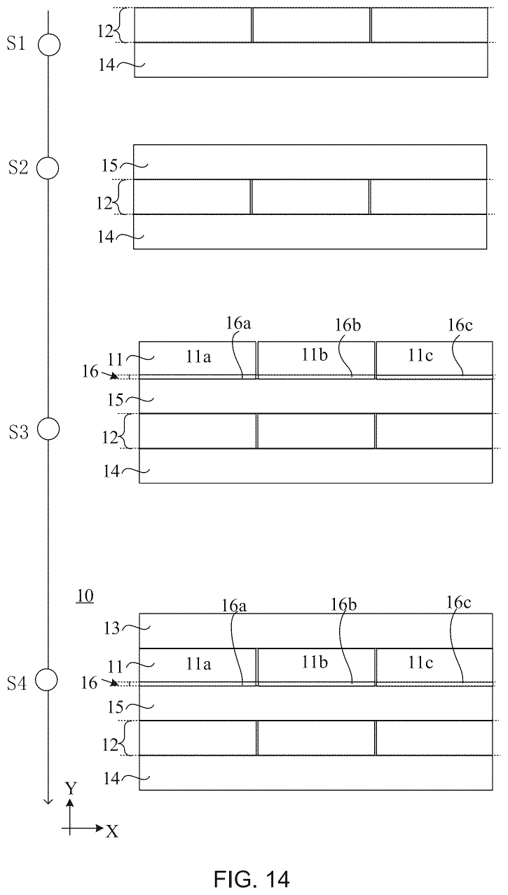

In S1, as shown in FIG. 14, a first electrode film layer 12 is formed on a substrate 14.

For example, the substrate 14 is any one of a glass substrate, a silicon wafer substrate, an S-G ZnO substrate, and a Sputter ZnO substrate.

For example, the first electrode film layer 12 is a cathode.

In S2, as shown in FIG. 14, a charge transport layer 15 is formed on a side of the first electrode film layer 12 away from the substrate.

For example, a sole-gel (s-g) ZnO solution is spin-coated and baked at 180° C. to form the charge transport layer 15. Alternatively, a charge transport layer 15, i.e., the electron transport layer, is formed by sputtering ZnO nanoparticles.

In S3, as shown in FIG. 14, a sacrificial layer 16 and a light-emitting layer 11 are formed on a side of the charge transport layer 15 away from the first electrode film layer 12, and the sacrificial layer 16 is disposed between the charge transport layer and the light-emitting layer 11.

For example, the sacrificial layer 16 includes a first sacrificial layer 16a, a second sacrificial layer 16b and a third sacrificial layer 16c that are arranged in a first direction X.

A material of the sacrificial layer 16 includes any one of the structures represented by the general formula III. Alternatively, the material of the sacrificial layer includes any one of the structures represented by the general formula IV.

That is to say, the material of the sacrificial layer 16 may be a cross-linked body material formed by nanoparticle materials and a cross-linking agent. Alternatively, the material of the sacrificial layer 16 may be a cross-linked body material formed by an organic insulating material and a cross-linking agent.

The light-emitting layer 11 includes a first quantum dot film layer 11a, a second quantum dot film layer 11b and a third quantum dot film layer 11c; the first quantum dot film layer 11a, the second quantum dot film layer 11b and the third quantum dot film layer 11c are arranged in the first direction X, and the first direction X is parallel to a plane where the light-emitting layer 11 is located. The first quantum dot film layer 11a, the second quantum dot film layer 11b, and the third quantum dot film layer 11c each include the cross-linked quantum dot material formed by the quantum dot material described in any of the above embodiments. The first quantum dot film layer 11a, the second quantum dot film layer 11b and the third quantum dot film layer 11c are configured to emit light of different colors.

For example, the first quantum dot film layer 11a is configured to emit red light, the second quantum dot film layer 11b is configured to emit blue light, and the third quantum dot film layer 11c is configured to emit green light, thereby realizing the full color display of the light-emitting device 10.

In S4, as shown in FIG. 14, a second electrode film layer 13 is formed on a side of the light-emitting layer 11 away from the sacrificial layer 16.

For example, the first electrode film layer 13 is an anode.

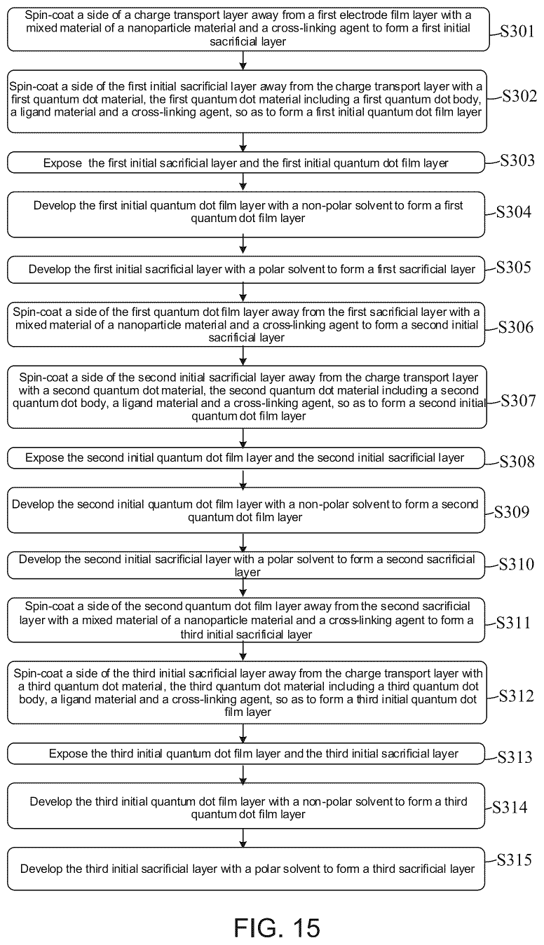

In some embodiments, as shown in FIGS. 15 to 18, step S3 of forming the sacrificial layer 15 and the light-emitting layer 11 on the side of the charge transport layer 15 away from the first electrode film layer 12 includes S301 to S315.

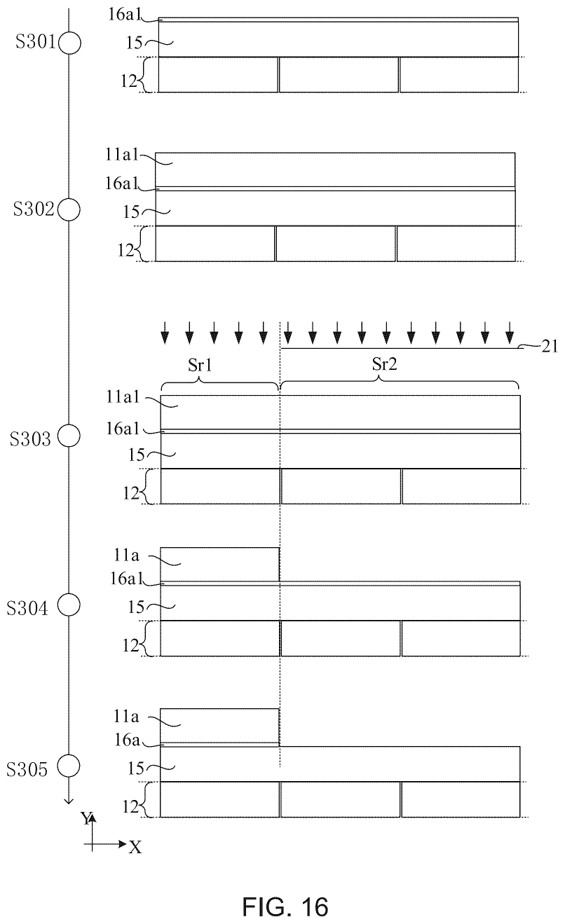

In S301, as shown in FIG. 16, a side of the charge transport layer 15 away from the first electrode film layer 12 is spin-coated with a mixed material of the nanoparticle material and cross-linking agent to form a first initial sacrificial layer 16a1.

For example, each cross-linker molecule contains two diazonaphthoquinone units. The mass of the cross-linking agent accounts for 0.5% to 10% of the mass of the nanoparticle material.

For example, the nanoparticle material is any one of ZnO, ZnMgO, ZrO₂, TiO₂, HfO₂ and ITO.

In S302, as shown in FIG. 16, a side of the first initial sacrificial layer 16a1 is away from the charge transport layer 15 is spin-coated with the first quantum dot material, the first quantum dot material including a first quantum dot body, a ligand material and a cross-linking agent, so as to form a first initial quantum dot film layer 11a1.

For example, the first quantum dot material is configured to emit red light.

As an example, the ligand material adopts an oleic acid ligand.

In S303, as shown in FIG. 16, the first initial sacrificial layer 16a1 and the first initial quantum dot film layer 11a1 are exposed.

For example, under a first mask 21, an exposure process is performed on an area Sr1 where a red sub-pixel to be formed, and the first quantum dot material in the area Sr1 is cross-linked under irradiation to form a cross-linked quantum dot material with a network structure; other areas are non-exposed areas Sr2, and the first quantum dot material in the non-exposed areas Sr2 is not cross-linked.

For example, the nanoparticle material and cross-linking agent in region Sr1 are cross-linked under irradiation to form a cross-linked network structure, and the nanoparticle material and the cross-linking agent in the non-exposed area Sr2 is not cross-linked.

In S304, as shown in FIG. 16, the first initial quantum dot film layer 11a1 is developed by using a non-polar solvent to form the first quantum dot film layer 11a.

For example, the first initial quantum dot film layer 11a1 is developed using a toluene solution; the solubility of the cross-linked quantum dot material with the network structure in the exposed area Sr1 is reduced, and the cross-linked quantum dot material is retained to form the first quantum dot film layer 11a, and the first quantum dot material in the non-exposed area Sr2 is eluted.

In S305, as shown in FIG. 16, the first initial sacrificial layer 16a1 is developed by using a polar solvent to form the first sacrificial layer 16a.

For example, the first initial sacrificial layer 16a1 is developed with ethanol; the solubility of the cross-linked nanoparticle material and cross-linking agent in the exposed area Sr1 is reduced, and the cross-linked nanoparticle material and cross-linking agent in the exposed area Sr1 is retained to form the first sacrificial layer 16a, and the nanoparticle material and the cross-linking agent in the non-exposed area Sr2 are eluted.

Moreover, the residual first quantum dot material bonded to the first initial sacrificial layer 16a1 and located in the non-exposed area Sr2 is eluted, thereby preventing cross-color interference of the residual first quantum dot material.

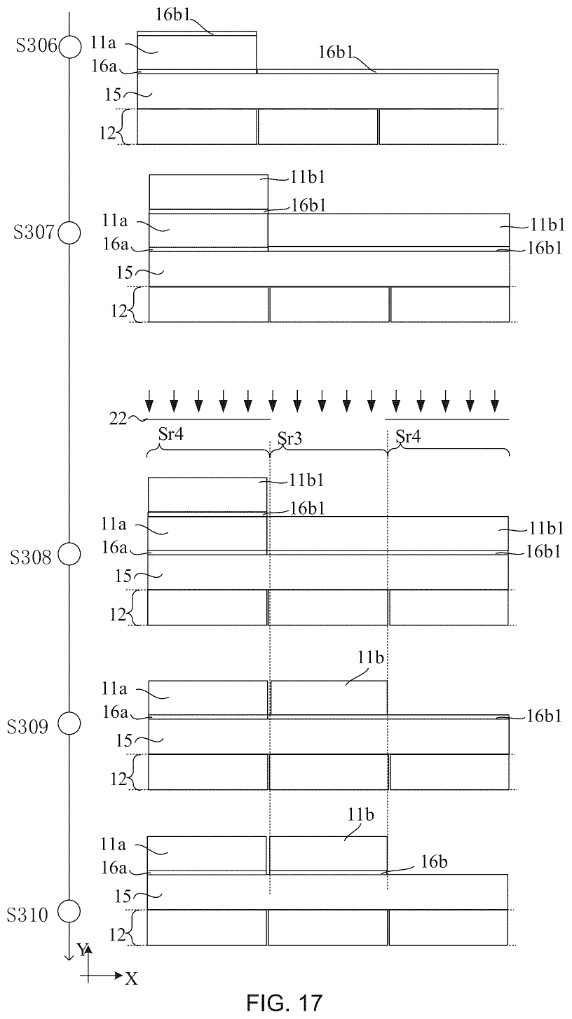

In S306, as shown in FIG. 17, the side of the first quantum dot film layer 11a away from the first sacrificial layer 16a is spin-coated with a mixed material of the nanoparticle material and the cross-linking agent to form a second initial sacrificial layer 16b1.

For example, the material of the second initial sacrificial layer 16b1 may refer to the material of the first initial sacrificial layer 16a1, which will not be repeated here.

In S307, as shown in FIG. 17, a side of the second initial sacrificial layer 16b1 away from the charge transport layer 15 is spin-coated with a second quantum dot material, the second quantum dot material including a second quantum dot body, a ligand material and a cross-linking agent, so as to form the second initial quantum dot film layer 11b1.

For example, the second quantum dot material is configured to emit blue light.

In S308, as shown in FIG. 17, the second initial quantum dot film layer 11b1 and the second initial sacrificial layer 16b1 are exposed.

For example, under a second mask 22, an exposure process is performed on an area Sr3 where a blue sub-pixel to be formed, and the second quantum dot material in the area Sr3 is cross-linked under irradiation to form a cross-linked quantum dot material with a network structure; other areas are non-exposed areas Sr4, and the second quantum dot material in the non-exposed areas Sr4 is not cross-linked.

For example, the nanoparticle material and the cross-linking agent in the Sr3 region are cross-linked under irradiation to form a cross-linked network structure, and the nanoparticle material and cross-linking agent in the non-exposed area Sr4 are not cross-linked.

In S309, as shown in FIG. 17, the second initial quantum dot film layer 11b1 is developed by using a non-polar solvent to form the second quantum dot film layer 11b.

For example, a toluene solution is used to develop the second initial quantum dot film layer 11b1; the solubility of the cross-linked quantum dot material with the network structure in the exposed area Sr3 is reduced, and the cross-linked quantum dot material is retained to form the second quantum dot film layer 11b, and the second quantum dot material in the non-exposed area Sr4 is eluted.

In S310, as shown in FIG. 17, the second initial sacrificial layer 16b1 is developed by using a polar solvent to form the second sacrificial layer 16b.

For example, ethanol is used to develop the second initial sacrificial layer 16b1; the solubility of the cross-linked nanoparticle material and cross-linking agent in the exposed area Sr3 is reduced, and the cross-linked nanoparticle material and cross-linking agent in the exposed area Sr3 is retained to form the second sacrificial layer 16b, and the nanoparticle material and the cross-linking agent in the non-exposed area Sr4 are eluted.

Moreover, the residual second quantum dot material bonded to the second initial sacrificial layer 16b1 and located in the non-exposed area Sr4 is eluted to prevent cross-color interference of the residual second quantum dot material.

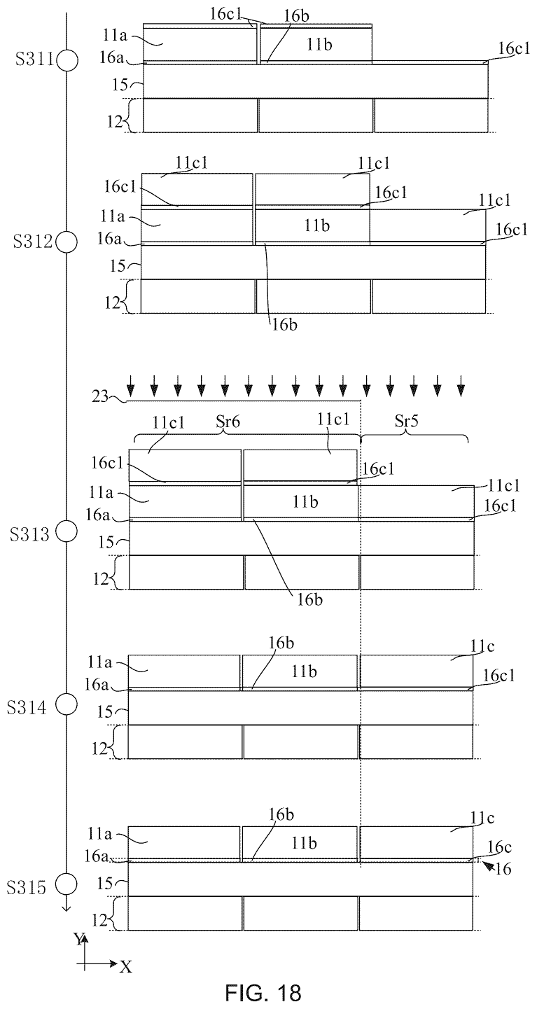

In S311, as shown in FIG. 18, a side of the second quantum dot film layer 11b away from the second sacrificial layer 16b is spin-coated with a mixed material of the nanoparticle material and the cross-linking agent to form a third initial sacrificial layer 16c1.

For example, the material of the third initial sacrificial layer 16c1 may refer to the material of the first initial sacrificial layer 16a1, which will not be repeated here.

In S312, as shown in FIG. 18, a side of the third initial sacrificial layer 16c1 away from the charge transport layer 15 is spin-coated with a third quantum dot material, the third quantum dot material including a third quantum dot body, a ligand material and a cross-linking agent, so as to form a third initial quantum dot film layer 11c1.

For example, the third quantum dot material is configured to emit green light.

In S313, as shown in FIG. 18, the third initial quantum dot film layer 11c1 and the third initial sacrificial layer 16c1 are exposed.

For example, under a third mask 23, an exposure process is performed on an area Sr5 where a green sub-pixel to be formed, and the third quantum dot material in the area Sr5 is cross-linked under irradiation to form a cross-linked quantum dot material with a network structure; the other areas are non-exposed areas Sr6, and the third quantum dot material in the non-exposed areas Sr6 is not cross-linked.

For example, the nanoparticle material and cross-linking agent in the area Sr5 are cross-linked under irradiation to form a cross-linked network structure, and the nanoparticle material and cross-linking agent in the non-exposed area Sr6 do not cross-link.

In S314, as shown in FIG. 18, the third initial quantum dot film layer 11c1 is developed by using a non-polar solvent to form the third quantum dot film layer 11c.

For example, the third initial quantum dot film layer 11c1 is developed by using a toluene solution; the solubility of the cross-linked quantum dot material with the network structure in the exposed area Sr5 is reduced, and the cross-linked quantum dot material with the network structure in the exposed area Sr5 is retained to form the third quantum dot film layer 11c, and the third quantum dot material in the non-exposed area Sr6 is eluted.

In S315, as shown in FIG. 18, the third initial sacrificial layer 16c1 is developed by using a polar solvent to form the third sacrificial layer 16c and the light-emitting layer 11.

For example, ethanol is used to develop the third initial sacrificial layer 16c1; the solubility of the cross-linked nanoparticle material and cross-linking agent in the exposed area Sr5 is reduced, and the cross-linked nanoparticle material and cross-linking agent in the exposed area Sr5 is retained to form the third sacrificial layer 16c, and the nanoparticle material and the cross-linking agent in the non-exposed area Sr6 are eluted.

Moreover, the residual third quantum dot material bonded to the third initial sacrificial layer 16c1 and located in the non-exposed area Sr6 is eluted to prevent cross-color interference of the residual third quantum dot material.

The sacrificial layer 16 includes a first sacrificial layer 16a, a second sacrificial layer 16b and a third sacrificial layer 16c.

Therefore, since there is a weaker force between the material forming the sacrificial layer 16 and the charge transport layer 15 compared to the quantum dot material, the arrangement of the sacrificial layer 16 may effectively avoid the residue of the quantum dot material and avoid the interference of cross-color.

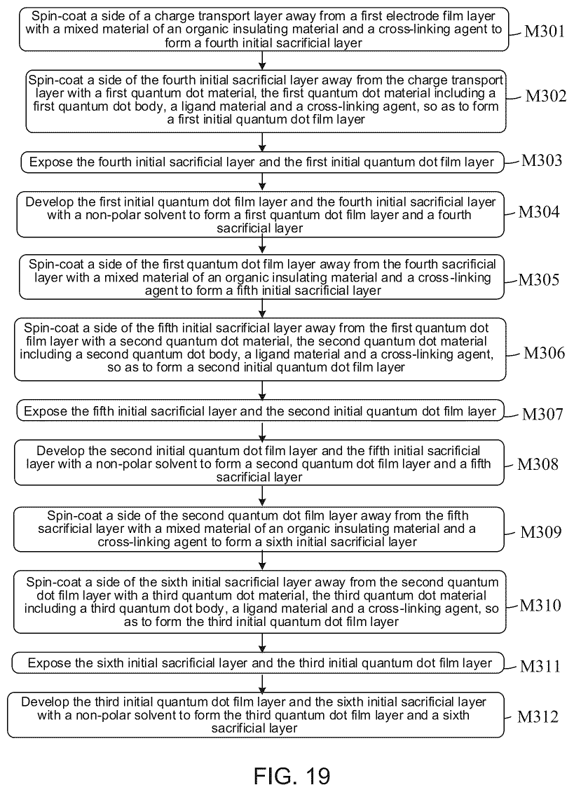

In some other embodiments, as shown in FIGS. 19 to 22, step S3 of forming the sacrificial layer 15 and the light-emitting layer 11 on the side of the charge transport layer 15 away from the first electrode film layer 12 includes M301 to M312.

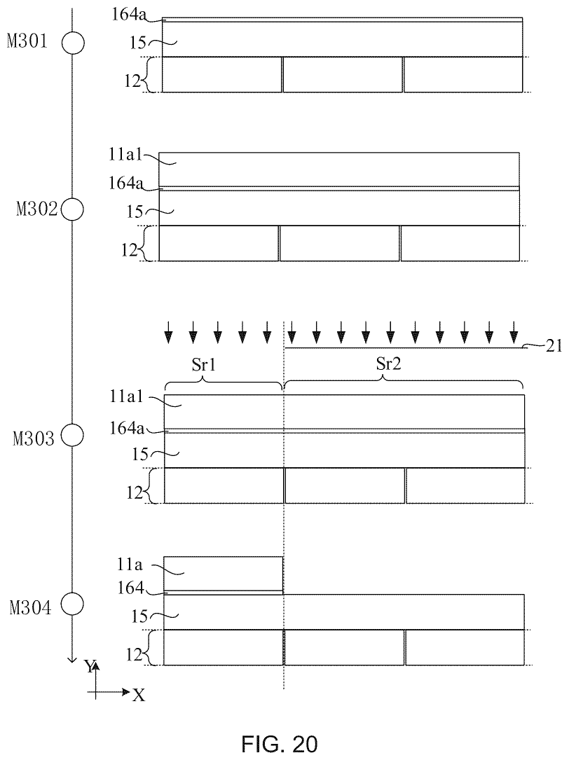

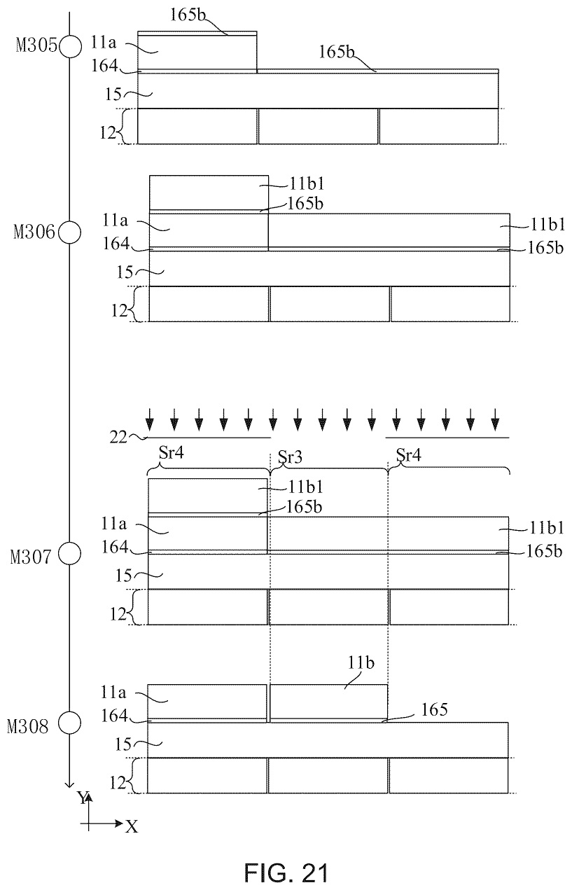

In M301, as shown in FIG. 20, a side of the charge transport layer 15 away from the first electrode film layer 12 is spin-coated with a mixed material of an organic insulating material and a cross-linking agent to form a fourth initial sacrificial layer 164a.

For example, the organic insulating material includes any one of polymethylmethacrylate and polyethyleneimine.

For example, the mass of the cross-linking agent accounts for 0.5% to 10% of the mass of the organic insulating material.

In M302, as shown in FIG. 20, a side of the fourth initial sacrificial layer 164a away from the charge transport layer 15 is spin-coated with a first quantum dot material, the first quantum dot material including a first quantum dot body, a ligand material and a cross-linking agent, so as to form the first initial quantum dot film layer 11a1.

For example, the first quantum dot material is configured to emit red light.

In M303, as shown in FIG. 20, the fourth initial sacrificial layer 164a and the first initial quantum dot film layer 11a1 are exposed.

For example, under a first mask 21, an exposure process is performed on an area Sr1 where a red sub-pixel to be formed, and the first quantum dot material in the area Sr1 is cross-linked under irradiation to form a cross-linked quantum dot material with a network structure; other areas are non-exposed areas Sr2, and the first quantum dot material in the non-exposed areas Sr2 is not cross-linked.

For example, the organic insulating material and cross-linking agent in the area Sr1 are cross-linked under irradiation to form a cross-linked structure, and the organic insulating material and cross-linking agent in the non-exposed area Sr2 are not cross-linked.

In M304, as shown in FIG. 20, the first initial quantum dot film layer 11a1 and the fourth initial sacrificial layer 164a are developed by using a non-polar solvent to form the first quantum dot film layer 11a and a fourth sacrificial layer 164.

For example, the first initial quantum dot film layer 11a1 and the fourth initial sacrificial layer 164a are developed using a toluene solution; the solubility of the cross-linked quantum dot material with the network structure in the exposed area Sr1 is reduced, and the cross-linked quantum dot material with the network structure in the exposed area Sr1 is retained to form the first quantum dot film layer 11a, and the first quantum dot material in the non-exposed area Sr2 is eluted.

Moreover, the solubility of the cross-linked organic insulating material and cross-linking agent in the exposed area Sr1 is reduced, and the cross-linked organic insulating material and cross-linking agent in the exposed area Sr1 is retained to form the fourth sacrificial layer 164, and the organic insulating material and cross-linking agent in the non-exposed area Sr2 are eluted.

In M305, as shown in FIG. 21, a side of the first quantum dot film layer 11a away from the fourth sacrificial layer 164 is spin-coated with a mixed material of an organic insulating material and a cross-linking agent to form a fifth initial sacrificial layer 165b.

For example, the material of the fifth initial sacrificial layer 165b may refer to the material of the fourth initial sacrificial layer 164a, which will not be repeated here.

In M306, as shown in FIG. 21, a side of the fifth initial sacrificial layer 165b away from the first quantum dot film layer 11a is spin-coated with a second quantum dot material, the second quantum dot material including a second quantum dot body and a ligand material, and a cross-linking agent, so as to form a second initial quantum dot film layer 11b1.

For example, the second quantum dot material is configured to emit blue light.

In M307, as shown in FIG. 21, the fifth initial sacrificial layer 165b and the second initial quantum dot film layer 11b1 are exposed.

For example, under a second mask 22, an exposure process is performed on an area Sr3 where a blue sub-pixel to be formed, and the second quantum dot material in the area Sr3 is cross-linked under irradiation to form a cross-linked quantum dot material with a network structure; the other areas are non-exposed areas Sr4, and the second quantum dot material in the non-exposed areas Sr4 is not cross-linked.

For example, the organic insulating material and cross-linking agent in region Sr3 are cross-linked under irradiation to form a cross-linked structure, and the organic insulating material and cross-linking agent in the non-exposed area Sr4 are not cross-linked.

In M308, as shown in FIG. 21, the second initial quantum dot film layer 11b1 and the fifth initial sacrificial layer 165b are developed by using a non-polar solvent to form the second quantum dot film layer 11b and the fifth sacrificial layer 165.

For example, a toluene solution is used to develop the second initial quantum dot film layer 11b1; the solubility of the cross-linked quantum dot material with the network structure in the exposed area Sr3 is reduced, and the cross-linked quantum dot material with the network structure is retained to form the second quantum dot film layer 11b, and the second quantum dot material in the non-exposed area Sr4 is eluted.

Moreover, the solubility of the cross-linked organic insulating material and cross-linking agent in the exposed area Sr3 is reduced, and the cross-linked organic insulating material and cross-linking agent in the exposed area Sr3 is retained to form a fifth sacrificial layer 165, and the organic insulating material and cross-linking agent in the non-exposed area Sr4 are eluted.

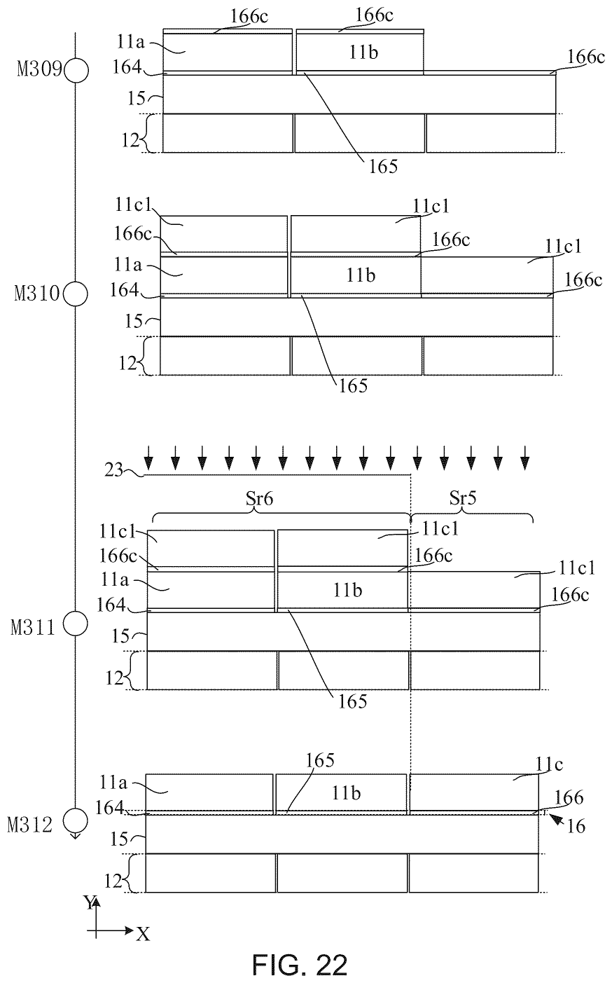

In M309, as shown in FIG. 22, a side of the second quantum dot film layer 11b away from the fifth sacrificial layer 165 is spin-coated with a mixed material of an organic insulating material and a cross-linking agent to form a sixth initial sacrificial layer 166c.

For example, the material of the sixth initial sacrificial layer 166c may refer to the material of the fourth initial sacrificial layer 164a, which will not be repeated here.

In M310, as shown in FIG. 22, a side of the sixth initial sacrificial layer 166c away from the second quantum dot film layer 11b is spin-coated with a third quantum dot material, the third quantum dot material including a third quantum dot body, a ligand material, and a cross-linking agent, so as to form a third initial quantum dot film layer 11c1.

For example, the third quantum dot material is configured to emit green light.

In M311, as shown in FIG. 22, the sixth initial sacrificial layer 166c and the third initial quantum dot film layer 11c1 are exposed.

For example, under a third mask 23, an exposure process is performed on an area Sr5 where a green sub-pixel to be formed, and the third quantum dot material in the area Sr5 is cross-linked under irradiation to form a cross-linked quantum dot material with a network structure; the other areas are non-exposed areas Sr6, and the third quantum dot material in the non-exposed areas Sr6 is not cross-linked.

For example, the organic insulating material and cross-linking agent in region Sr5 are cross-linked under irradiation to form a cross-linked structure, and the organic insulating material and cross-linking agent in the non-exposed area Sr6 are not cross-linked.

In M312, as shown in FIG. 22, a non-polar solvent is used to develop the third initial quantum dot film layer 11c1 and the sixth initial sacrificial layer 166c to form the third quantum dot film layer 11c and the sixth sacrificial layer 166.

For example, the third initial quantum dot film layer 11c1 is developed by using a toluene solution; the solubility of the cross-linked quantum dot material with the network structure in the exposed area Sr5 is reduced, and the cross-linked quantum dot material with the network structure in the exposed area Sr5 is retained to form the third quantum dot film layer 11c, and the third quantum dot material in the non-exposed area Sr6 is eluted.

Moreover, the solubility of the cross-linked organic insulating material and cross-linking agent in the exposed area Sr5 is reduced, and the cross-linked organic insulating material and cross-linking agent in the exposed area Sr5 is retained to form a sixth sacrificial layer 166, and the organic insulating material and cross-linking agent in the non-exposed area Sr6 are eluted.

The sacrificial layer 16 includes the fourth sacrificial layer 164, the fifth sacrificial layer 165 and the sixth sacrificial layer 166.

Therefore, with the direct patterning method provided by the technical solutions of the present disclosure, the construction of multi-layer patterned film layers only requires repeated spin coating, exposure, and development, so that it is easily to construct red, green, and blue full-color patterned devices and is easily to operate.

It will be noted that the quantum dot material provided by the embodiments of the present disclosure is used to form the cross-linked quantum dot material under irradiation to fabricate the light-emitting layer 11, and the body material and the cross-linking agent provided by the embodiments of the present disclosure are used to form the cross-linked body material under irradiation to fabricate a sacrificial material layer 16. The above-mentioned embodiments are all illustrated by considering an inverted light-emitting device as an example, and the above-mentioned materials and manufacturing methods provided by the embodiments of the present disclosure may also be used for the upright light-emitting device, which will not be repeated here.

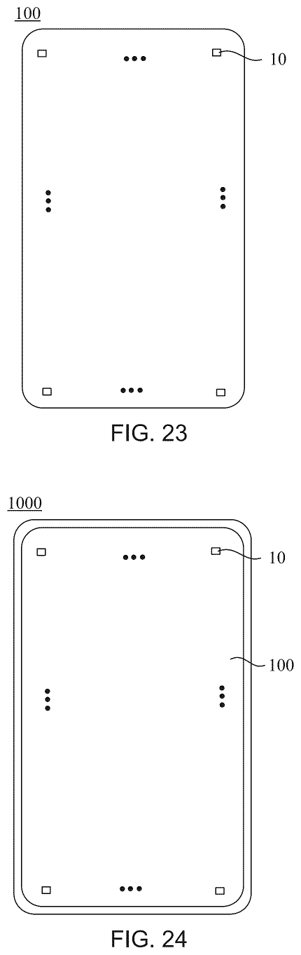

Some embodiments of the present disclosure provide a display substrate 100, as shown in FIG. 23, the display substrate 100 includes the light-emitting device 10 provided by any of the above embodiments.

The beneficial effects that can be achieved by the display substrate 100 are the same as the beneficial effects that can be achieved by the light-emitting device 10 provided by the embodiments of the present disclosure, which will not be repeated here.

Some embodiments of the present disclosure provide a display apparatus 1000. As shown in FIG. 24, the display apparatus 1000 includes the display substrate 100 described above.

The display apparatus 1000 may be any apparatus that displays images whether in motion (e.g., a video) or stationary (e.g., a still image), and regardless of text or image. More specifically, it is expected that the embodiments may be implemented in or associated with a plurality of electronic devices. The plurality of electronic devices may include (but are not limit to), mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (e.g., odometer displays), navigators, cockpit controllers and/or displays, camera view displays (e.g., rear view camera displays in vehicles), electronic photos, electronic billboards or indicators, projectors, building structures, packagings and aesthetic structures (e.g., a display for an image of a piece of jewelry).

In some examples, in a case where the display apparatus 1000 is an electroluminescent display apparatus, the electroluminescent display apparatus may be an organic electroluminescent display apparatus or a quantum dot electroluminescent display apparatus.

The beneficial effects that can be achieved by the display apparatus 1000 are the same as the beneficial effects that can be achieved by the light-emitting device 10 provided by the embodiments of the present disclosure, which will not be repeated here.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A quantum dot material, comprising: a quantum dot body and a ligand material coordinately bonded to the quantum dot body;
further comprising: a cross-linking agent, the cross-linking agent including at least two diazonaphthoquinone units; wherein each diazonaphthoquinone unit of the at least two diazonaphthoquinone units is configured to undergo a photochemical reaction under irradiation to generate a carbene intermediate; the ligand material is configured to be bonded to the carbene intermediate through an addition reaction to form a cross-linked quantum dot material.

2. The quantum dot material according to claim 1, wherein the ligand material includes an alkyl carbon-hydrogen bond, and the alkyl carbon-hydrogen bond of the ligand material is configured to be bonded to the carbene intermediate through a carbon-hydrogen insertion addition reaction; or
the ligand material includes a hydroxyl group, and the hydroxyl group in the ligand material is configured to be bonded to the carbene intermediate through an addition reaction to form an ether compound; or
the ligand material includes an amino group, and the amino group in the ligand material is configured to be bonded to the carbene intermediate through a nitrogen-hydrogen insertion addition reaction; or
the ligand material includes a carboxyl group, and the carboxyl group in the ligand material is configured to be bonded to the carbene intermediate through an addition reaction to form an ester compound.

3. The quantum dot material according to claim 1, wherein the cross-linking agent is selected from any one of structures represented by following general formula I; 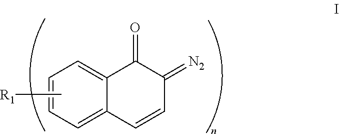
where R₁ is selected from any one of substituted or unsubstituted alkanes, substituted or unsubstituted heterocyclic compounds, and substituted or unsubstituted aromatic hydrocarbons; and
a value of n is selected from an integer greater than or equal to 2.

4. (canceled)

5. The quantum dot material according to claim 1, wherein the cross-linking agent is selected from any one of structures represented by following general formula I-A; 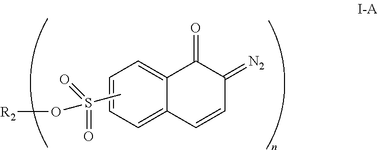
where R₂ is selected from any one of substituted or unsubstituted alkanes, substituted or unsubstituted heterocyclic compounds, and substituted or unsubstituted aromatic hydrocarbons; and
a value of n is selected from an integer greater than or equal to 2.

6. The quantum dot material according to claim 1, wherein the ligand material includes any one of oleic acid, oleylamine, isooctylthiol and octylthiol; and/or
a mass of the cross-linking agent accounts for 5% to 10% of a mass of the quantum dot body.

7. (canceled)

8. The quantum dot material according to claim 1, wherein the formed cross-linked quantum dot material is selected from any one of structures represented by following general formula II; 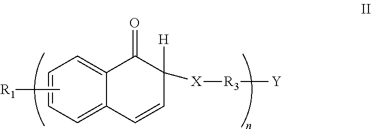
where X is selected from any one of single bonds, oxygen groups, imino groups, and ester groups;
R₃ is selected from any one of —COO— containing C1-C40 carbon chains, —NH— containing C1-C40 carbon chains, —S— containing C1-C40 carbon chains, and organophosphorus compounds containing C1-C40 carbon chains;
R₁ is selected from any one of substituted or unsubstituted alkanes, substituted or unsubstituted heterocyclic compounds, and substituted or unsubstituted aromatic hydrocarbons;
a value of n is selected from an integer greater than or equal to 2; and
Y represents the quantum dot body.

9. The quantum dot material according to claim 8, wherein the formed cross-linked quantum dot material is selected from any one of structures represented by following general formula II-A; 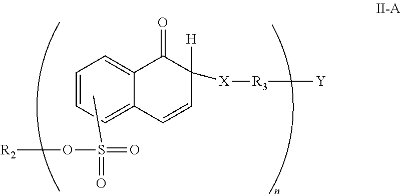
where R₂ is selected from any one of substituted or unsubstituted alkanes, substituted or unsubstituted heterocyclic compounds, and substituted or unsubstituted aromatic hydrocarbons.

10. The quantum dot material according to claim 1, wherein a solubility of the cross-linked quantum dot material in a non-polar solvent is less than a solubility of the quantum dot material in the non-polar solvent; or
the solubility of the cross-linked quantum dot material in the non-polar solvent is less than the solubility of the quantum dot material in the non-polar solvent, and the non-polar solvent includes any one of octane, toluene and xylene.

11. (canceled)

12. A light-emitting device, comprising: a light-emitting layer, the light-emitting layer including the cross-linked quantum dot material formed by the quantum dot material according to claim 1.

13. The light-emitting device according to claim 12, wherein the light-emitting layer includes a first quantum dot film layer, a second quantum dot film layer and a third quantum dot film layer; the first quantum dot film layer, the second quantum dot film layer and the third quantum dot film layer are arranged in a first direction; the first direction is parallel to a plane where the light-emitting layer is located; and
the light-emitting layer further includes a first electrode film layer, a charge transport layer and a second electrode film layer, wherein the first electrode film layer, the charge transport layer, the light-emitting layer and the second electrode film layer are arranged in sequence in a second direction, the second direction is perpendicular to the first direction.

14. The light-emitting device according to claim 13, wherein a first quantum dot material forming the first quantum dot film layer includes a cross-linking agent, and the cross-linking agent includes at least four diazonaphthoquinone units.

15. The light-emitting device according to claim 12, wherein the cross-linked quantum dot material is selected from any one of structures represented by following general formula II; 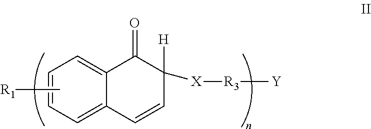
where X is selected from any one of single bonds, oxygen groups, imino groups, and ester groups;
R₃ is selected from any one of —COO— containing C1-C40 carbon chains, —NH— containing C1-C40 carbon chains, —S— containing C1-C40 carbon chains, and organophosphorus compounds containing C1-C40 carbon chains;
R₁ is selected from any one of substituted or unsubstituted alkanes, substituted or unsubstituted heterocyclic compounds, and substituted or unsubstituted aromatic hydrocarbons;
a value of n is selected from an integer greater than or equal to 2; and
Y represents the quantum dot body.

16. The light-emitting device according to claim 15, wherein the cross-linked quantum dot material is selected from any one of structures represented by following general formula II-A; 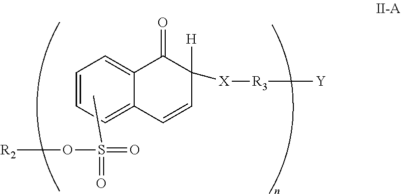
where R₂ is selected from any one of substituted or unsubstituted alkanes, substituted or unsubstituted heterocyclic compounds, and substituted or unsubstituted aromatic hydrocarbons.

17. (canceled)

18. The light-emitting device according to claim 13, further comprising: a sacrificial layer, the sacrificial layer being disposed between the charge transport layer and the light-emitting layer; wherein
the sacrificial layer includes a cross-linked body material, and a material for forming the cross-linked body material includes the cross-linking agent and a body material, and the cross-linking agent includes at least two diazonaphthoquinone units; each diazonaquinone unit of the at least two diazonaquinone units is configured to undergo a photochemical reaction under irradiation to generate a carbene intermediate; the body material is bonded to the carbene intermediate through an addition reaction to form the cross-linked body material; or the carbene intermediate is configured to generate a unit containing a carboxyl group, and the body material is configured to be cross-linked through the carboxyl group to form the cross-linked body material; wherein the charge transport layer includes any one of an electron transport layer and a hole transport layer; or
the sacrificial layer includes a cross-linked body material, and the cross-linked body material is selected from any one of structures represented by following general formula III: 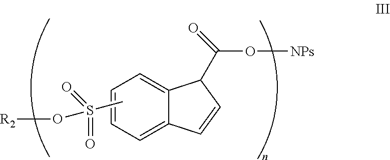
where R₂ is selected from any one of substituted or unsubstituted alkanes, substituted or unsubstituted heterocyclic compounds, and substituted or unsubstituted aromatic hydrocarbons;
a value of n is selected from any one of 2, 3, 4, 5 and 6;
NPs represents a nanoparticle material; and
multiple units each containing a carboxyl group formed by the cross-linking agent after irradiation are bonded to the NPs; or
the sacrificial layer includes a cross-linked body material, and the cross-linked body material is selected from any one of structures represented by following general formula IV; 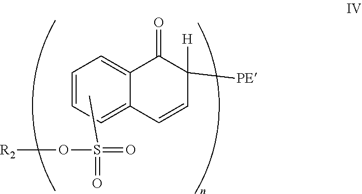
where R₂ is selected from any one of substituted or unsubstituted alkanes, substituted or unsubstituted heterocyclic compounds, and substituted or unsubstituted aromatic hydrocarbons;
a value of n is selected from any one of 2, 3, 4, 5 and 6; and
PE′ represents a group formed by a hydrocarbon insertion addition reaction between an organic insulating material and the cross-linking agent.

19-21. (canceled)

22. The light emitting device according to claim 18, wherein in a case where the cross-linked body material is selected from any one of the structures represented by the general formula III, the nanoparticle material includes any one of ZnO, ZnMgO, ZrO₂, TiO₂, HfO₂ and ITO; or
in a case where the cross-linked body material is selected from any one of the structures represented by the general formula IV, the organic insulating material is selected from any of polymethylmethacrylate and polyethyleneimine.

23. The light-emitting device according to claim 18, wherein
the body material includes the nanoparticle material, and a mass of the cross-linking agent accounts for 0.5% to 10% of a mass of the nanoparticle material; or,
the body material includes the organic insulating material, and a mass of the cross-linking agent accounts for 0.5% to 10% of a mass of the insulating material.

24. A manufacturing method for a light-emitting device, comprising:
forming a first electrode film layer on a substrate;
forming a charge transport layer on a side of the first electrode film layer away from the substrate;
forming a sacrificial layer and a light-emitting layer on a side of the charge transport layer away from the first electrode film layer, the sacrificial layer being located between the charge transport layer and the light-emitting layer; wherein
a material of the sacrificial layer includes any one of structures represented by a following general formula III or general formula IV; 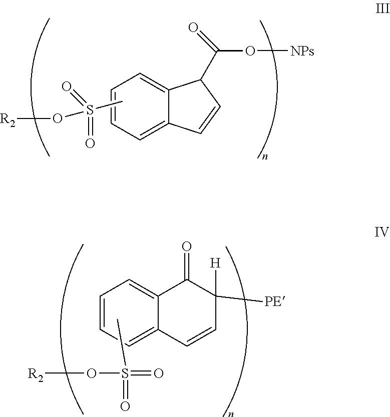
where R₂ is selected from any one of substituted or unsubstituted alkanes, substituted or unsubstituted heterocyclic compounds, and substituted or unsubstituted aromatic hydrocarbons;
a value of n is selected from any one of 2, 3, 4, 5 and 6;
NPs represents a nanoparticle material; and
PE′ represents a group formed by a hydrocarbon insertion addition reaction between an organic insulating material and the cross-linking agent; and
the light-emitting layer includes a first quantum dot film layer, a second quantum dot film layer and a third quantum dot film layer formed in sequence; the first quantum dot film layer, the second quantum dot film layer and the third quantum dot film layer are arranged in a first direction, and the first direction is parallel to a plane where the light-emitting layer is located; the first quantum dot film layer, the second quantum dot film layer and the third quantum dot film layer each include the cross-linked quantum dot material formed by the quantum dot material according to claim 1; the first quantum dot film layer, the second quantum dot film layer and the third quantum dot film layer are configured to emit light of different colors; and
forming a second electrode film layer on a side of the light-emitting layer away from the sacrificial layer.

25. The method according to claim 24, wherein forming the sacrificial layer and the light-emitting layer on the side of the charge transport layer away from the first electrode film layer includes:
spin-coating the side of the charge transport layer away from the first electrode film layer with a mixed material of a nanoparticle material and a cross-linking agent to form a first initial sacrificial layer;
spin-coating a side of the first initial sacrificial layer away from the charge transport layer with a first quantum dot material, the first quantum dot material including a first quantum dot body, a ligand material and a cross-linking agent, so as to form a first initial quantum dot film layer;
exposing the first initial sacrificial layer and the first initial quantum dot film layer;
developing the first initial quantum dot film layer with a non-polar solvent to form the first quantum dot film layer;
developing the first initial sacrificial layer with a polar solvent to form a first sacrificial layer;
spin-coating a side of the first quantum dot film layer away from the first sacrificial layer with a mixed material of a nanoparticle material and a cross-linking agent to form a second initial sacrificial layer;
spin-coating a side of the second initial sacrificial layer away from the charge transport layer with a second quantum dot material, the second quantum dot material including a second quantum dot body, a ligand material and a cross-linking agent, so as to form a second initial quantum dot film layer;
exposing the second initial quantum dot film layer and the second initial sacrificial layer;
developing the second initial quantum dot film layer with a non-polar solvent to form the second quantum dot film layer;
developing the second initial sacrificial layer with a polar solvent to form a second sacrificial layer;
spin-coating a side of the second quantum dot film layer away from the second sacrificial layer with a mixed material of a nanoparticle material and a cross-linking agent to form a third initial sacrificial layer;
spin-coating a side of the third initial sacrificial layer away from the charge transport layer with a third quantum dot material, the third quantum dot material including a third quantum dot body, a ligand material and a cross-linking agent, so as to form a third initial quantum dot film layer;
exposing the third initial quantum dot film layer and the third initial sacrificial layer;
developing the third initial quantum dot film layer with a non-polar solvent to form the third quantum dot film layer; and
developing the third initial sacrificial layer with a polar solvent to form a third sacrificial layer;
wherein the sacrificial layer includes the first sacrificial layer, the second sacrificial layer and the third sacrificial layer.

26. The method according to claim 24, wherein forming the sacrificial layer and the light-emitting layer on the side of the charge transport layer away from the first electrode film layer includes:
spin-coating the side of the charge transport layer away from the first electrode film layer with a mixed material of an organic insulating material and a cross-linking agent to form a fourth initial sacrificial layer;
spin-coating a side of the fourth initial sacrificial layer away from the charge transport layer with a first quantum dot material, the first quantum dot material including a first quantum dot body, a ligand material and a cross-linking agent, so as to form a first initial quantum dot film layer;
exposing the fourth initial sacrificial layer and the first initial quantum dot film layer;
developing the first initial quantum dot film layer and the fourth initial sacrificial layer with a non-polar solvent to form the first quantum dot film layer and a fourth sacrificial layer;
spin-coating a side of the first quantum dot film layer away from the fourth sacrificial layer with a mixed material of an organic insulating material and a cross-linking agent to form a fifth initial sacrificial layer;
spin-coating a side of the fifth initial sacrificial layer away from the first quantum dot film layer with a second quantum dot material, the second quantum dot material including a second quantum dot body, a ligand material and a cross-linking agent, so as to form a second initial quantum dot film layer;
exposing the fifth initial sacrificial layer and the second initial quantum dot film layer;
developing the second initial quantum dot film layer and the fifth initial sacrificial layer with a non-polar solvent to form the second quantum dot film layer and a fifth sacrificial layer;
spin-coating a side of the second quantum dot film layer away from the fifth sacrificial layer with a mixed material of an organic insulating material and a cross-linking agent to form a sixth initial sacrificial layer;
spin-coating a side of the sixth initial sacrificial layer away from the second quantum dot film layer with a third quantum dot material, the third quantum dot material including a third quantum dot body, a ligand material and a cross-linking agent, so as to form the third initial quantum dot film layer;
exposing the sixth initial sacrificial layer and the third initial quantum dot film layer; and
developing the third initial quantum dot film layer and the sixth initial sacrificial layer with a non-polar solvent to form the third quantum dot film layer and a sixth sacrificial layer;
wherein the sacrificial layer includes the fourth sacrificial layer, the fifth sacrificial layer and the sixth sacrificial layer.

27. A display apparatus, comprising the light-emitting device according to claim 12.
